(19) United States
(12) Patent Application Publication
(10) Pub. No.: US 2025/0183220 A1
(43) Pub. Date: Jun. 5, 2025

(54) ELECTRONIC COMPONENT AND DEVICE INCLUDING THE ELECTRONIC COMPONENT

(71) Applicant: CANON KABUSHIKI KAISHA, Tokyo (JP)

(72) Inventors: YU KATASE, Kanagawa (JP); KOICHI SHIMIZU, Kanagawa (JP)

(21) Appl. No.: 18/959,382

(22) Filed: Nov. 25, 2024

(30) Foreign Application Priority Data
Nov. 30, 2023 (JP) 2023-202720
Sep. 13, 2024 (JP) 2024-159060

(51) Int. Cl. H01L 23/00; H01L 23/38; H01L 27/146

(52) U.S. Cl. CPC H01L 24/48; H01L 23/38; H01L 24/49; H10F 39/804; H10F 39/811; H01L 24/32; H01L 24/45; H01L 24/73; H01L 2224/32225; H01L 2224/45124; H01L 2224/45144; H01L 2224/48091; H01L 2224/48108; H01L 2224/48227; H01L 2224/48453; H01L 2224/48464; H01L 2224/4903; H01L 2224/49109; H01L 2224/49171; H01L 2224/49505

(57) ABSTRACT

An electronic component includes a cooling member, a semiconductor substrate, and a base member in which the cooling member and the semiconductor substrate are placed, wherein the cooling member is arranged between the base member and the semiconductor substrate, wherein the semiconductor substrate includes a first electrode, wherein the base member includes a second electrode, wherein the first electrode and the second electrode are connected by a conductive wire, and wherein balls are formed on both of a bonded portion of the first electrode and the conductive wire, and a bonded portion of the second electrode and the conductive wire.

### BACKGROUND

### Field

The present disclosure relates to an electronic component and a device including the electronic component.

### Description of the Related Art

Japanese Patent Application Laid-Open No. 2006-191465 discusses an electronic device including a Peltier element and an image sensor.

### SUMMARY

According to some embodiments of the present disclosure, an electronic component includes a cooling member, a semiconductor substrate, and a base member in which the cooling member and the semiconductor substrate are placed, wherein the cooling member is arranged between the base member and the semiconductor substrate, wherein the semiconductor substrate includes a first electrode, wherein the base member includes a second electrode, wherein the first electrode and the second electrode are connected by a conductive wire, and wherein balls are formed on both of a bonded portion of the first electrode and the conductive wire, and a bonded portion of the second electrode and the conductive wire.

Further features of the present disclosure will become apparent from the following description of exemplary embodiments with reference to the attached drawings.

### BRIEF DESCRIPTION OF THE DRAWINGS

FIG. 1 is a schematic cross-sectional view of an electronic component according to a first exemplary embodiment.

FIG. 2 is a schematic top view of the electronic component according to the first exemplary embodiment.

FIGS. 3A and 3B are schematic bottom views of the electronic component according to the first exemplary embodiment.

FIG. 4 is a schematic view of the electronic component according to the first exemplary embodiment.

FIGS. 5A to 5C are schematic views of the electronic component according to the first exemplary embodiment.

FIGS. 6A and 6B are diagrams illustrating a comparative example of a method for bonding a wire of the electronic component according to the first exemplary embodiment.

FIG. 7 is a diagram illustrating a method for bonding a wire of the electronic component according to the first exemplary embodiment.

FIG. 8 is a diagram illustrating a comparative example of a method for bonding a wire of the electronic component according to the first exemplary embodiment.

FIG. 9 is a schematic view of a cooling member of an electronic component according to a second exemplary embodiment.

FIGS. 10A to 10C are schematic cross-sectional views of an electronic component according to the second exemplary embodiment.

FIGS. 11A to 11F are schematic cross-sectional views of the electronic component according to the second exemplary embodiment.

FIG. 12 is a schematic cross-sectional view of the electronic component according to the second exemplary embodiment.

FIGS. 13A to 13C are schematic views of the cooling member of the electronic component according to the second exemplary embodiment.

FIG. 14 is a schematic cross-sectional view illustrating a modified example of the electronic component according to the second exemplary embodiment.

FIG. 15 is a schematic cross-sectional view of an electronic component according to a third exemplary embodiment.

FIG. 16 is a schematic top view of the electronic component according to the third exemplary embodiment.

FIGS. 17A and 17B are schematic cross-sectional views of the electronic component according to the third exemplary embodiment.

FIG. 18 is a schematic cross-sectional view of the electronic component according to the third exemplary embodiment.

FIG. 19 is a schematic top view of the electronic component according to the third exemplary embodiment.

FIGS. 20A and 20B are schematic cross-sectional views of the electronic component according to the third exemplary embodiment.

FIG. 21 is a schematic top view of the electronic component according to the third exemplary embodiment.

FIGS. 22A and 22B are schematic cross-sectional views of the electronic component according to the third exemplary embodiment.

FIGS. 23A and 23B are schematic cross-sectional views of an electronic component according to a fourth exemplary embodiment.

FIG. 24 is a schematic cross-sectional view of an electronic component according to a fifth exemplary embodiment.

FIG. 25 is a schematic cross-sectional view of the electronic component according to the fifth exemplary embodiment.

FIGS. 26A to 26D are schematic cross-sectional views of the electronic component according to the fifth exemplary embodiment.

FIG. 27 is a functional block diagram of a photoelectric conversion system according to a sixth exemplary embodiment.

FIGS. 28A and 28B are functional block diagrams of a photoelectric conversion system according to a seventh exemplary embodiment.

FIG. 29 is a functional block diagram of a photoelectric conversion system according to an eighth exemplary embodiment.

FIG. 30 is a functional block diagram of a photoelectric conversion system according to a ninth exemplary embodiment.

FIGS. 31A and 31B are diagrams of a photoelectric conversion system according to a tenth exemplary embodiment.

### DESCRIPTION OF THE EMBODIMENTS

In order to prevent interference between a bonding capillary and a substrate when performing wire bonding of the substrate on which an image sensor is arranged and a package base member in which the substrate is to be placed, it is difficult to reduce the size of an electronic component. The technique of the present disclosure provides an electronic component that allows wire bonding between a substrate and a package base member in which the substrate is to be placed to be desirably performed.

The following exemplary embodiments are provided to embody the technical idea of the present disclosure and are not intended to limit the present disclosure. The sizes and the positional relationship of members illustrated in the drawings are sometimes exaggerated to clarify the description. In the following description, the same components are assigned the same reference numerals, and the description thereof will be sometimes omitted.

Hereinafter, various exemplary embodiments, features, and aspects of the present disclosure will be described in detail with reference to the drawings. In the following description, terms (e.g., “up”, “down”, “right”, “left”, and other terms including these terms) indicating specific directions and positions are used as appropriate. These terms are used to facilitate the understanding of the exemplary embodiments to be described with reference to the drawings. The technical scope of the present disclosure is not limited by the meanings of these terms.

In this specification, a “planar view” refers to a view from a direction vertical to a light incidence surface of a semiconductor layer. A cross-sectional view refers to a view of a surface in the direction vertical to the light incidence surface of the semiconductor layer. In a case where the light incidence surface of the semiconductor layer is a rough surface when viewed microscopically, a planar view is defined based on the light incidence surface of the semiconductor layer that when viewed macroscopically.

The semiconductor layer has a first surface that light enters, and a second surface on the opposite side of the first surface. In this specification, a depth direction refers to a direction extending from the first surface to the second surface of the semiconductor layer on which a photodiode (PD) is arranged. A “depth” of a certain point or a certain region in the semiconductor layer means a distance of the point or the region from the first surface. When a point (or region) Z1 with a distance (depth) d1 from the first surface and a point (or region) Z2 with a distance (depth) d2 from the first surface exist, and d1>d2 is satisfied, such a state is sometimes represented as “the point Z1 is deeper than the point Z2” or “the point Z2 is shallower than the point Z1”. When there additionally exists a point (or region) Z3 with a distance (depth) d3 from the first surface, and d1>d3>d2 is satisfied, such a state is sometimes represented as “the point Z3 exists between the depths of the points Z1 and Z2” or “the point Z3 exists between the points Z1 and Z2 in the depth direction”.

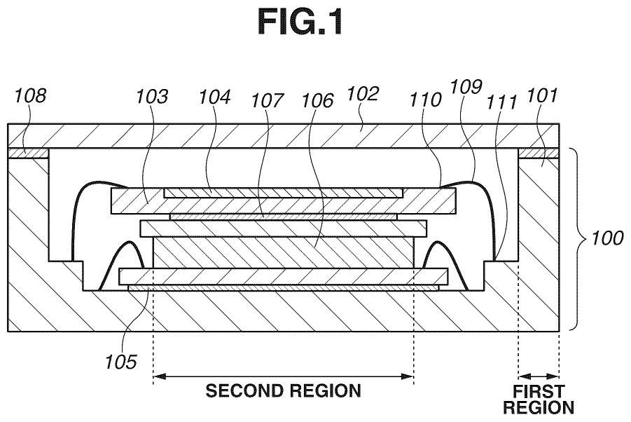

An electronic component according to a first exemplary embodiment of the present disclosure will be described with reference to FIGS. 1 to 8.

In an electronic component equipped with an image sensor, noise is sometimes generated due to a temperature change in the image sensor. For noise reduction, a cooling member for cooling a semiconductor chip on which the image sensor is placed can be further placed in a package in which the semiconductor chip is to be placed. As an example of a member to be used in the cooling of the semiconductor chip, there is a Peltier element. In the following exemplary embodiment, an electronic component including an image sensor and a Peltier element will be described, but the cooling member is not limited to the Peltier element and may be a cooling fin or a heat pipe, for example.

FIG. 1 is a cross-sectional view illustrating an example of a configuration of an electronic component according to the first exemplary embodiment.

The electronic component includes a package 100 including abase member 101, and an optical member 102 bonded to a frame member of the base member 101 by an optical member adhesive 108. A Peltier element 106 is bonded to a bottom portion of the base member 101 by a Peltier adhesive 105, and furthermore, a semiconductor substrate 103 is bonded by a semiconductor substrate adhesive 107. The semiconductor substrate 103 is electrically connected with the base member 101 by a conductive wire 109.

The base member 101 is formed of alumina or ceramic, such as aluminum nitride, as a main material. This is because such a material has high thermal conductivity, so that heat generated in the Peltier element 106 can be easily released to the outside of the package 100.

The optical member 102 is formed of glass, crystal, or sapphire, for example. The crystal and the sapphire also function as a low-pass filter (LPF). The sapphire has high strength and can be made thin as compared with the crystal. In other words, the sapphire is advantageous in reducing the size of the entire package 100. Because a linear expansion coefficient of the sapphire is nearly equal to a linear expansion coefficient of the alumina, if the optical member 102 is made of sapphire in a case where the base member 101 is made of alumina, bonding reliability is high.

The semiconductor substrate 103 is a silicon substrate, for example, and is provided with a pixel region 104 in which a plurality of image sensors is arranged in an array. The image sensor may be, for example, a complementary metal-oxide semiconductor (CMOS) image sensor or may be an avalanche diode. In a case where the image sensor is an avalanche diode, the avalanche diode may be a single photon avalanche diode (SPAD).

The optical member adhesive 108 is an epoxy adhesive, for example. The optical member adhesive 108 may be an ultraviolet cure adhesive or a thermosetting adhesive, but the optical member adhesive 108 is desirably an adhesive with low moisture permeability that can secure airtightness, because the inside of the base member 101 is kept under N₂ atmosphere or in a vacuum state for heat insulation.

In order to keep low moisture permeability, it is desirable that an adhesive thickness of the optical member adhesive 108 is thin and an adhesive width of the optical member adhesive 108 is wide. For example, the thickness of the optical member adhesive 108 is desirably 20 micrometers (μm) to 30 μm or less. The adhesive width can be set from the viewpoint of the size reduction, bonding reliability, and moisture permeability of the package 100.

The Peltier adhesive 105 and the semiconductor substrate adhesive 107 are desirably made of material with high thermal conductivity, such as silver paste. Because a space generated between bonded surfaces hinders thermal conduction, these adhesives are desirably applied to the bonded surfaces as wide as possible, or the entire surfaces. Adhesive thicknesses of the Peltier adhesive 105 and the semiconductor substrate adhesive 107 are each about 100 μm or less, and are desirably about 20 μm to 30 μm in particular.

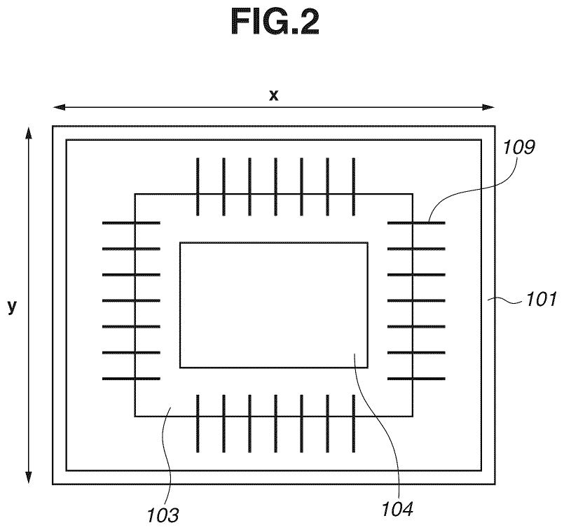

FIG. 2 is a plan view of the electric component according to the present exemplary embodiment that is viewed from the optical member 102 side.

At the center of the electronic component, the pixel region 104 of the rectangular semiconductor substrate 103 is arranged, and a plurality of conductive wires 109 is provided on each side. When a length in a longer direction of the electronic component is denoted by x, and a length in a shorter direction is denoted by y, the electronic component is assumed to have a size with about 20 millimeters (mm) of the lengths x and y, but the size of the electronic component is not limited to this.

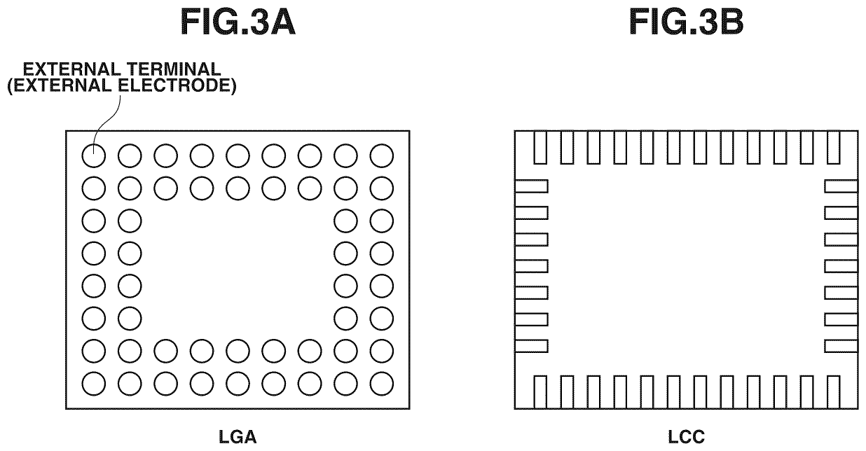

FIGS. 3A and 3B are plan views of the electronic component according to the present exemplary embodiment that is viewed from the optical member 102 side. FIG. 3A is a schematic view illustrating a case where the package 100 is a so-called land grid array (LGA), and FIG. 3B is a schematic view illustrating a case where the package 100 is a so-called leadless ceramic chip carrier (LCC).

The configuration of an electrode for connecting to the outside of the package 100 may be the LGA or the LCC, or may be a pin grid array (PGA). From the viewpoint of reducing the size, the LGA is desirable because a low height can be realized as compared with other configurations. Alternatively, a configuration obtained by combining the LGA and the LCC may be employed.

In a case where the LGA is employed as the configuration of the package 100, it can be manufactured by using a reflow furnace, and improvement in productivity can be expected as compared with other methods. At this time, in order to prevent the Peltier element 106 from being damaged due to the melting of solder contained in the Peltier element 106 in the reflow processing, the temperature of the reflow furnace to be used in the manufacturing of the electronic component according to the present exemplary embodiment needs to be low temperature (200° C. (Celsius) or less). For this reason, the bonding with the outside is implemented using material with a low melting point, such as resin reinforced solder.

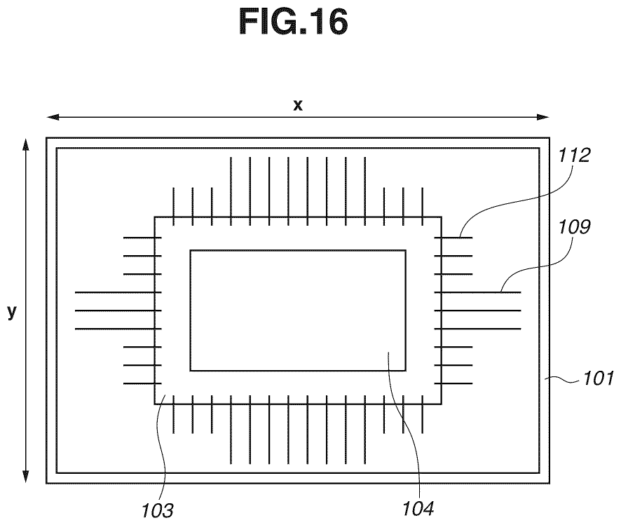

As a terminal array of the LGA, a portion with no terminal is desirably provided at the center portion as illustrated in FIG. 3A. By bonding a member with high thermal conductivity to the portion with no terminal to release heat of the base member 101 to the outside, the cooling efficiency of the Peltier element 106 can be increased. As the member with high thermal conductivity, for example, a carbon graphite sheet, an alloy plate for heat spreader, or a heat pipe can be used. As illustrated in FIG. 16, a path for releasing heat to the outside can be formed by putting a carbon graphite sheet 403 with one end portion bonded to the electronic component, to the outside of the electronic component through an opening portion provided on a polychlorinated biphenyl (PCB) substrate 401, and connecting the other end portion to a casing of a camera module.

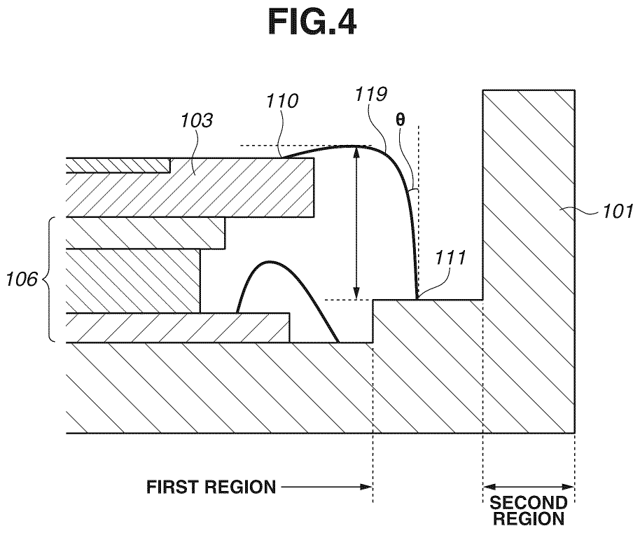

FIG. 4 is a schematic view illustrating a portion near a bonded portion of the base member 101 and the conductive wire 119 of the electronic component according to the present exemplary embodiment in an enlarged state. The illustration of the Peltier adhesive 105 and the semiconductor substrate adhesive 107 is omitted.

A first electrode 110 provided on the semiconductor substrate 103 and a second electrode 111 provided on the base member 101 are connected by the conductive wire 119. When a region of the bottom portion of the base member 101 in which the frame member is provided is regarded as a first region, and a region in which the Peltier element 106 is placed is regarded as a second region, the second electrode 111 is arranged between the first region and the second region. In FIG. 4, the second electrode 111 is provided on a surface protruding toward the semiconductor substrate 103 side as compared with a surface of the base member 101 on which the Peltier element 106 is placed. This is a configuration for preventing interference between the base member 101 and a capillary, which will be described below, and the second electrode 111 may be provided on the surface of the base member 101 on which the Peltier element 106 is placed. Here, if an angle formed by the conductive wire 119 and a normal line of the surface on which the second electrode 111 is arranged is denoted by θ, in order to reduce the size of the electronic component, the second electrode 111 is desirably provided at a position closer to the semiconductor substrate 103, and the angle θ is 10° or less, for example.

In the electronic component in which the Peltier element 106 is placed together with the semiconductor substrate 103 as in the present exemplary embodiment, the conductive wire 119 connecting the semiconductor substrate 103 and the base member 101 desirably has a fixed length in order to prevent a return heat flow from the Peltier element 106, and the second electrode 111 is desirably provided at a low position to ensure a wire length.

A distance in a vertical direction between the surface on which the second electrode 111 is provided and an uppermost part of the conductive wire 119 is 1 mm or more. The distance in the vertical direction of the conductive wire 119 is determined based on the thickness of the Peltier element 106 and the chip thickness of the semiconductor substrate 103. In the present exemplary embodiment, in order to maintain the thickness of the semiconductor substrate 103, backgrinding is not performed, and the semiconductor substrate 103 has a thickness of about 0.7 mm to 0.8 mm. In a case where backgrinding is not performed, thermal conductivity in a direction parallel to the flat surface of the semiconductor substrate 103 becomes high, and an effect of uniformly keeping a temperature distribution within the surface of the image sensor becomes high, which is more desirable. In the case of performing backgrinding on the semiconductor substrate 103, by setting the substrate thickness to about 0.5 mm, the distance in the vertical direction is ensured.

Similarly, the distance in the vertical direction of the conductive wire 119 can be also extended by increasing the thickness of the Peltier element 106. Nevertheless, if the Peltier element 106 is thick, a capillary to be used in wire bonding might interfere with the base member 101.

The conductive wire 119 is desirably thinner than a wire to be generally used in an image sensor not equipped with the Peltier element 106. For example, the size of the conductive wire 119 is desirably Φ15 μm. This is because when wire thermal resistance becomes high, it is possible to prevent a heat flow from returning to the semiconductor substrate 103 from the Peltier element 106 via the base member 101. Furthermore, in order to enhance thermal resistance, a wire to be used as the conductive wire 119 is desirably a wire with thermal conductivity smaller than 300 W/mK (Watts per meter Kelvin) that contains a gold alloy or aluminum as a main material, rather than a gold wire. To prevent a wire breakage, a wire diameter of the conductive wire 119 is determined based on balance between an allowable current amount, resistance, and inductance.

On the other hand, because power consumption of the Peltier element 106 is large, a wire diameter of a wire electrically connecting the Peltier element 106 and the base member 101 is desirably thick. A member connecting the Peltier element 106 and the base member 101 is not limited to the wire and may be a conductive adhesive, such as silver paste, or solder.

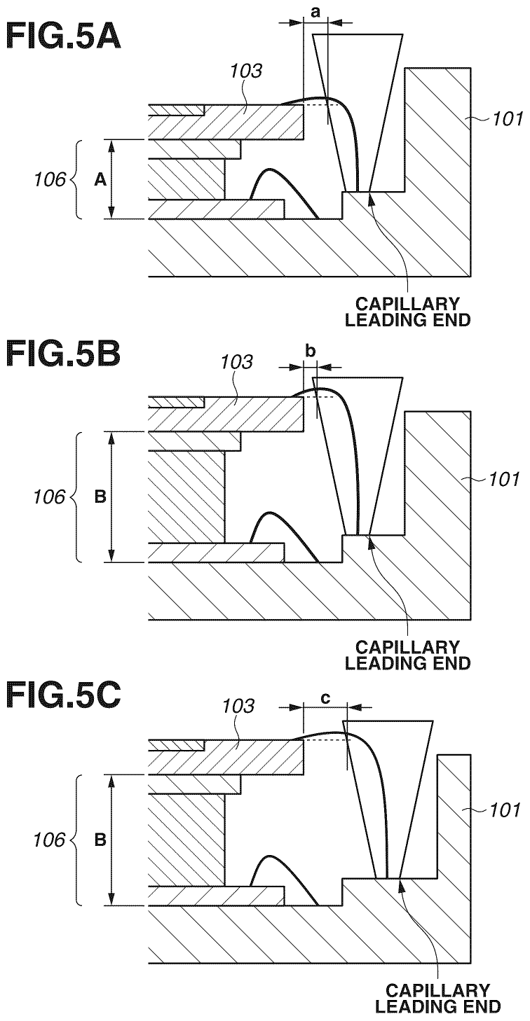

FIGS. 5A to 5C are diagrams illustrating a minimum clearance between a bonding capillary and a chip. For example, in a case where the Peltier element 106 with a thickness A is used as illustrated in FIG. 5A, a distance between an upper end of the semiconductor substrate 103 and a point where a capillary comes closest to the semiconductor substrate 103 at the same height as the upper end of the semiconductor substrate 103 is denoted by “a”. On the other hand, in a case where the Peltier element 106 with a thickness B is used as illustrated in FIG. 5B, a distance between the upper end of the semiconductor substrate 103 and a capillary is denoted by “b”. For example, in a case where the same base member 101 is used, if the thicknesses satisfy the relationship of A<B, the distances satisfy the relationship of a>b.

The minimum clearance between the semiconductor substrate 103 and the capillary varies depending on the size of the semiconductor substrate 103 and the position of the second electrode 111. In a case where the Peltier element 106 with the same thickness B as that in FIG. 5B is used, by shifting the position of the second electrode 111 in a direction of getting away from the semiconductor substrate 103 in a planar view, as illustrated in FIG. 5C, a distance c between the semiconductor substrate 103 and the capillary can be ensured. Alternatively, it is also possible to ensure the distance c also by bringing the surface of the base member 101 on which the second electrode 111 is provided closer to the semiconductor substrate 103, i.e., by shifting the position of the second electrode 111 upward.

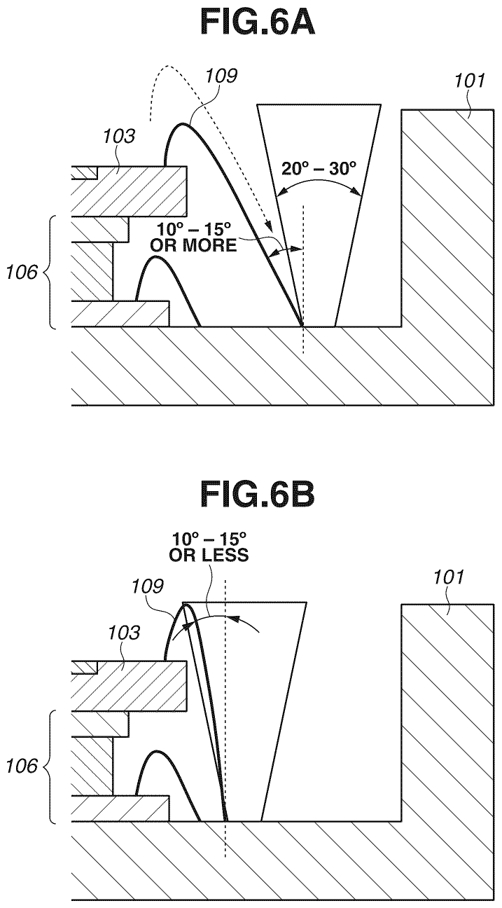

FIGS. 6A and 6B are diagrams illustrating a relationship between a wire angle and a capillary angle in bringing down a capillary onto the base member 101 in general wire bonding. FIG. 6A is a diagram illustrating a case where the angle θ is 10° to 15° or more, and FIG. 6B is a diagram illustrating a case where the angle θ is 10° to 15° or less.

As illustrated in FIG. 6A, in general wire bonding, after the first electrode 110 and the conductive wire 109 are bonded, a wire loop is formed, and the second electrode 111 and the conductive wire 109 are bonded by stitch bonding. At this time, the leading end of the capillary used in bonding has an angle of about 20° to 30° in a cross section. As illustrated in FIG. 6B, in a case where bonding is performed in a state in which the wire angle θ is an angle steeper than the angle of the capillary, the bonding cannot be performed because the capillary and the wire interfere with each other. Because a space in a horizontal direction between the second electrode 111 and an end portion of the base member 101 is desirable to increase the angle θ, this prevents a reduction in the size of the electronic component.

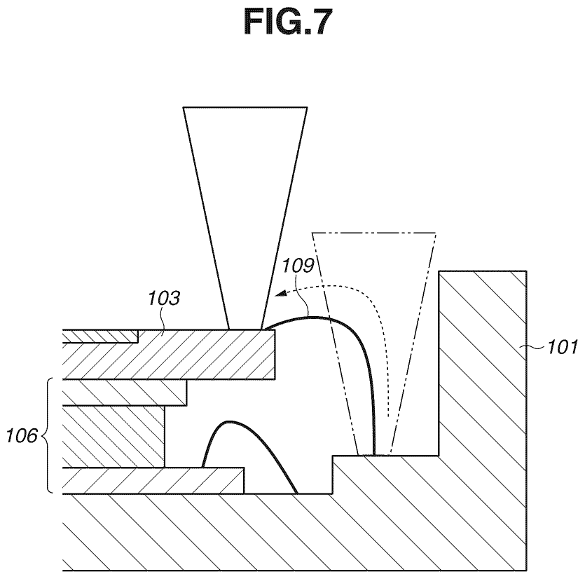

FIG. 7 is a diagram illustrating a relationship between a wire angle and a capillary angle in wire bonding of a ball stitch on bonding (BSOB) method. In this method, first of all, a ball is formed on the first electrode 110. After that, the second electrode 111 and the conductive wire 109 are bonded, the capillary is raised almost vertically, and the first electrode 110 and the conductive wire 109 are bonded. In other words, balls are formed in both of a bonded portion of the first electrode 110 and the conductive wire 109 and a bonded portion of the second electrode 111 and the conductive wire 109, and bonding is performed. A stitch is formed on the ball at the bonded portion of the second electrode 111 and the conductive wire 109, and the second electrode 111 and the conductive wire 109 are bonded. In this bonding method, as long as a distance that allows bonding of the conductive wire 109 and the second electrode 111 is ensured, irrespective of a distance between the second electrode 111 and the end portion of the base member 101, interference does not occur between the capillary and the conductive wire 109 in bonding the conductive wire 109 to the semiconductor substrate 103. Accordingly, it is possible to reduce a space in the horizontal direction as compared with a case where the conductive wire 109 is bonded using a normal bonding method, and it is consequently possible to reduce the size of the electronic component.

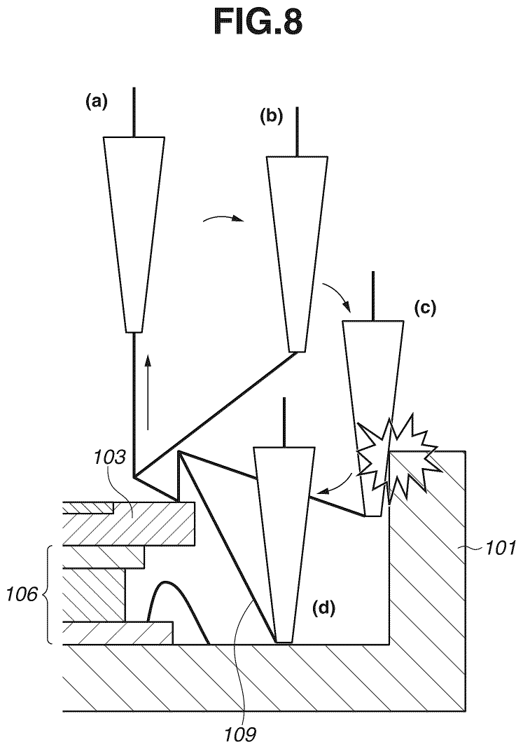

A space desirable in a case where normal wire bonding is performed will be further described with reference to FIG. 8. A general wire bonding flow is schematically illustrated with reference to FIGS. 6A and 6B. More specifically, the bonding of the conductive wire 109 is performed while the capillary is moved in the order of (a), (b), (c), and (d) in FIG. 8.

By forming a ball on the first electrode 110 and performing pressure bonding while applying heat and ultrasonic waves, the first electrode 110 and the conductive wire 109 are bonded. After that, a bend point is formed in the conductive wire 109, and the conductive wire 109 is drawn out by a desirable length. By pressure-bonding the conductive wire 109 to the second electrode 111 while maintaining tension in such a manner as to prevent the drawn the conductive wire 109 from getting loose, a stitch is formed at the bonded portion. In a case where the height of the second electrode 111 is lower than the height of the semiconductor substrate 103, if a wall surface of the base member 101 exists on a trajectory drawn by the capillary, the capillary and the base member 101 interfere with each other. To prevent the interference, a space in the horizontal direction is desirable between the second electrode 111 and the end portion of the base member 101, and this leads to an increase in the size of the electronic component.

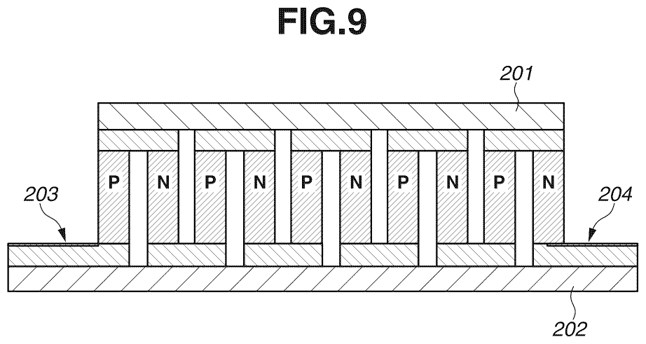

An electronic component according to a second exemplary embodiment will be described with reference to FIGS. 9 to 13C. The description of parts that overlaps the description of the electronic component according to the first exemplary embodiment will be omitted, and a difference from the first exemplary embodiment will be mainly described.

A Peltier element 106 to be mounted on the electronic component according to the present exemplary embodiment will be described with reference to FIG. 9. The Peltier element 106 has a configuration in which P-type semiconductors and N-type semiconductors are alternately arranged and coupled with metal electrodes in a π shape between upper and lower heatsinks.

One of the upper and lower heatsinks is a heat absorption surface 201, and the other one is a heat generation surface 202. In the electronic component according to the present exemplary embodiment of the present disclosure, the heat absorption surface 201 faces the semiconductor substrate 103 and the heat generation surface 202 faces the base member 101. The heatsinks are made of alumina or aluminum nitride, and their thermal conductivity may be increased by processing, such as gold plating processing. If the materials of the base member 101 and the heatsinks are the same, a linear expansion coefficient difference is not generated, which is advantageous in terms of stress. The Peltier element 106 has a conducting space including electrodes 203 and 204 for conduction with the outside. For example, the electrode 203 is an electrode connected with a power source, and the electrode 204 is an electrode connected with the ground.

When a voltage V is applied to the Peltier element 106, a current I flows. A heat absorption surface temperature is denoted by T_{c} and a heat generation surface temperature is denoted by Tₕ. When a Seebeck coefficient is denoted by α, an internal resistance is denoted by R, a thermal conductivity is denoted by λ, and a temperature difference between the heat absorption surface temperature and the heat release surface temperature is denoted by ΔT, a heat absorption amount Qc is represented by the following equation.

$${Q}_{c} = α {T}_{c} I - λΔ T - \frac{1}{2} R {I}^{2}$$

In other words, the thermal conductivity λ and the internal resistance R are desirably small in order to increase the heat absorption amount Qc of the Peltier element 106.

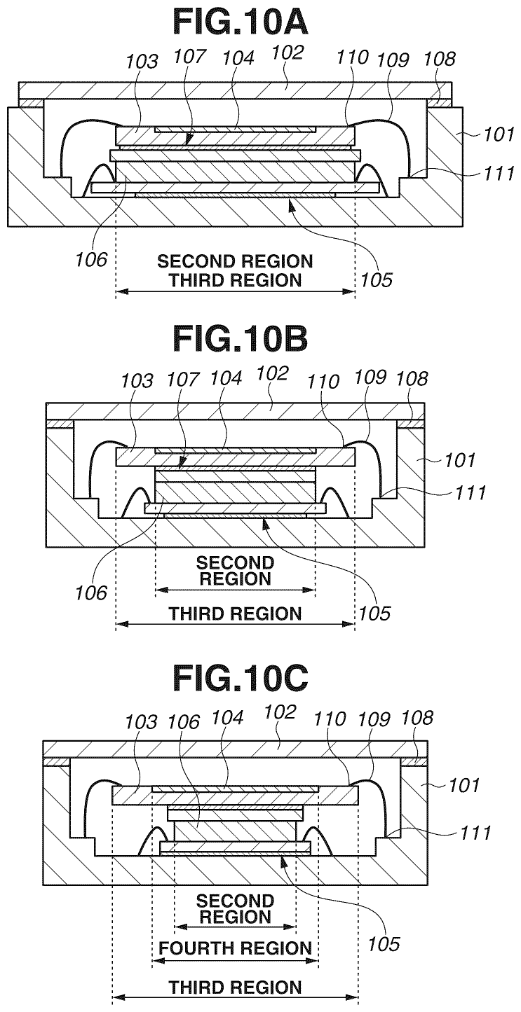

Variations of the Peltier element 106 will be described with reference to FIGS. 10A to 10C.

In an electronic component illustrated in FIG. 10A, the Peltier element 106 has a size equal to the size of the semiconductor substrate 103. In other words, the size of the second region is equal to the size of a third region where the semiconductor substrate 103 and a bottom portion overlap each other. In this case, it is easy to uniformly cool the inside of the surface of the semiconductor substrate 103, but the thermal conductivity λ in the above-described equation becomes large and power consumption increases. A heat release amount on the heat generation side therefore increases as well. This may make it difficult to suppress Heat flow, and the total power consumption of the product may increase, which is disadvantageous. In addition, the conducting space in which the first electrode 110 is provided is outside the second region, which is disadvantageous in terms of reducing the size of a chip.

In an electronic component illustrated in FIG. 10B, the entire Peltier element 106 including the conducting space has a size encompassed in the second region in which the semiconductor substrate 103 is arranged, and the Peltier element 106 has a size encompassed in the pixel region 104 of the semiconductor substrate 103. Also in this case, while it is easy to uniformly cool the inside of the surface of the semiconductor substrate 103, the thermal conductivity λ is large and power consumption increases. A heat release amount on the heat generation side therefore increases as well. Consequently, this may make it difficult to suppress heat flow, and total power consumption may increase.

In an electronic component illustrated in FIG. 10C, the entire Peltier element 106 including the conducting space fits within the size of the semiconductor substrate 103. Furthermore, a second region in which the Peltier element 106 is arranged is smaller than a fourth region in which the pixel region 104 and a bottom portion overlap each other.

In a standard Peltier element, the smaller an area of a heatsink is, the smaller the thermal conductivity λ can be. Nevertheless, because the heat absorption amount Qc accordingly decreases, it is important to select a Peltier element including an appropriate number of P-type semiconductors and an appropriate number of N-type semiconductors.

In a case where a targeted cooling temperature of the image sensor is denoted by Tc, a temperature of the base member 101 on the heat release side is denoted by Th, and a thermal resistance of a plurality of conductive wires 109 is denoted by Rw, heat Pw returning to the semiconductor substrate 103 from the base member 101 through the entire conductive wire 109 is represented by (Th−Tc)/Rw. To keep the cooling temperature Tc of the image sensor constant, the sum of power consumption Ps of the image sensor and the heat Pw that transmits through the conductive wire 109 is to be equal to the heat absorption amount Qc of the Peltier element 106.

In order to save power consumption Pp of the Peltier element 106 under such a condition, it is desirable to select a Peltier element 106 including P-type semiconductors and N-type semiconductors of which the numbers make COP=Qc/Pp, which indicates a ratio between the heat absorption amount Qc and the power consumption of the Peltier element 106, the largest. In a case where a widely mass-produced bismuth telluride Peltier element is used in the cooling of the image sensor, as illustrated in FIG. 10C, by selecting a Peltier element having a small size compared with the size of the image sensor, i.e., by selecting a Peltier element including a relatively small number of P-type and N-type elements and a small thermal conductivity a, it makes it possible to efficiently absorb heat, and it often makes it possible to save the total power consumption of the product.

Nevertheless, in a case where the first electrode 110 is bonded at a position overlapping, in a planar view, a hollow region where the Peltier element 106 is not arranged below the semiconductor substrate 103, heat and ultrasonic waves may not be easily transmitted to a bonded portion from a stage for heating that is provided below the package 100.

Because the Peltier element 106 is small and a region holding the semiconductor substrate 103 is narrow, when wire bonding is performed, load may be applied to the bonded surface of the semiconductor substrate 103 and the Peltier element 106 according to the principle of the wire bonding. Furthermore, temperature unevenness may be generated on the surface of the semiconductor substrate 103.

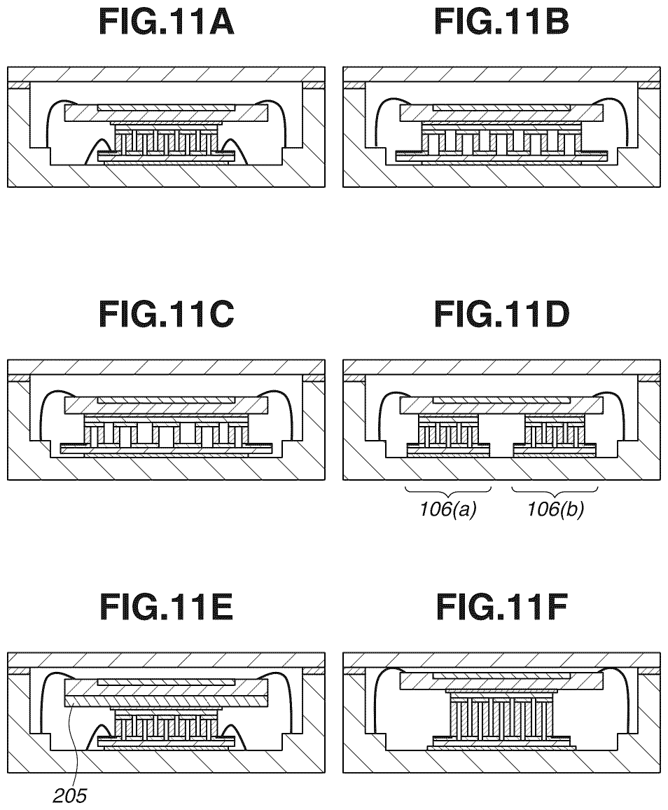

A modified example of the Peltier element 106 will be further described with reference to FIGS. 11A to 11F.

FIG. 11A illustrates an electronic component including a Peltier element 106 smaller in size than the pixel region 104 of the semiconductor substrate 103 described with reference to FIG. 10C. For example, a case is assumed where the semiconductor substrate 103 has the size of about 15.5 mm×11.2 mm (the pixel region 104 has the size of 13 mm×10 mm), and the Peltier element 106 has the size of about 6 mm×6 mm. As described above, in terms of wire the performance of wire bonding, strength, and temperature unevenness, this configuration has issues to be solved.

FIG. 11B illustrates an electronic component in which sizes of heatsinks of the Peltier element 106 in a x-y direction are enlarged and the numbers of P-type semiconductors and N-type semiconductors included in the Peltier element 106 and thermal resistance are kept equal to those in the case illustrated in FIG. 11A. The Peltier element 106 is widened to be at least larger than the pixel region 104. The Peltier element 106 may be enlarged up to a position overlapping the first electrode 110 in a planar view, for example. With such a configuration, it is possible to expand a region below the semiconductor substrate 103 that is held by the Peltier element 106, while maintaining the cooling capacity of the Peltier element 106 illustrated in FIG. 11A, and the value of the above-described COP. In other words, wire bonding becomes easier and the prevention of temperature unevenness and improvement in strength can be expected.

FIG. 11C illustrates a Peltier element 106 in which an interval between an N-type semiconductor and a P-type semiconductor is increased compared to the Peltier element 106 illustrated in FIG. 11B, N-type semiconductors and P-type semiconductors are sparsely arranged in a part near the center part of the electronic component, and N-type semiconductors and P-type semiconductors are densely arranged on an outer peripheral portion side.

Also in this case, the cooling capacity, the thermal resistance, and the COP remain unchanged from those of the Peltier elements 106 illustrated in FIGS. 11A and 11B. By employing such a configuration of the Peltier element 106, it makes it easier to perform wire bonding and temperature unevenness can be prevented. Furthermore, by densely arranging the electrodes of the element on the outer peripheral side of the electronic component, strength in bonding is ensured, and improvement in reliability (temperature cycle resistance) is expected.

FIG. 11D illustrates an electronic component in which a plurality of compact Peltier elements 106 is arranged. The plurality of Peltier elements 106 may be connected in series or may be connected in parallel. In a case where the plurality of Peltier elements 106 is connected in series, a current I increases, and in a case where the plurality of Peltier elements 106 is connected in parallel, a voltage V increases. In a cross section illustrated in FIG. 11D, two Peltier elements 106(a) and 106(b) are illustrated, but the number of Peltier elements 106 to be connected is not limited to this, and three or more Peltier elements 106 may be connected.

In such a configuration, wire bonding can be easily performed, and it is possible to prevent temperature unevenness and ensure strength.

FIG. 11E is a diagram illustrating an electronic component including a compact Peltier element 106 similarly to that in FIG. 11A. As a difference from FIG. 11A, the electronic component illustrated in FIG. 11E includes a heat spreader 205 made of an alloy that is provided between the semiconductor substrate 103 and the Peltier element 106. The heat spreader 205 is provided to promote heat conduction and simultaneously reinforce the strength of the semiconductor substrate 103.

A copper (Cu) alloy is desirably used as the heat spreader 205. The heat spreader 205 desirably has a thickness of about 0.5 mm, and desirably exists over the entire region below the semiconductor substrate 103. In this case, in order to prevent the thickness from being increased, the thickness of the semiconductor substrate 103 may be decreased by backgrinding.

Even with such a configuration, it is possible to facilitate wire bonding and also obtain effects of preventing temperature unevenness and ensuring strength.

FIG. 11F illustrates an electronic component including the Peltier element 106 having a size in a planar view that is equal to that of Peltier element 106 in FIG. 11A but having a greater height than that of the Peltier element 106 in FIG. 11A. In the same cross section, the greater the height of the Peltier element 106 is, the smaller an operating current amount I of the Peltier element 106 is and the larger an operating voltage V is. Because the smaller current is, the more joule loss in a wire is suppressed, an effect of saving the total power consumption is obtained.

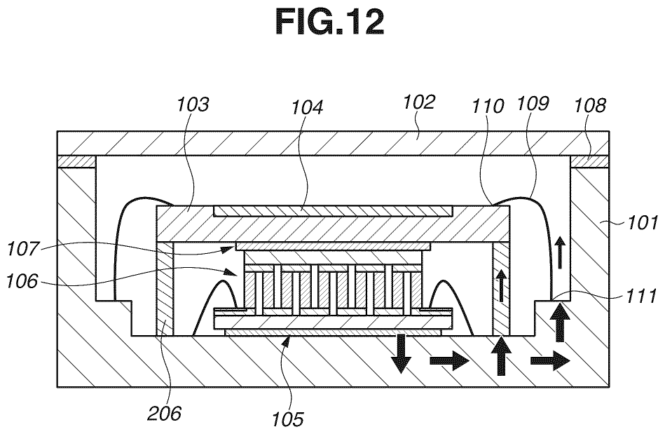

FIG. 12 illustrates another modified example of the electronic components illustrated in FIGS. 11A to 11F. As described above, in a case where a wire is bonded at a position overlapping, in a planar view, a region where the Peltier element 106 is not arranged below the semiconductor substrate 103, heat and ultrasonic waves may not be easily transmitted to a bonded portion from a stage for heating that is provided below the base member 101.

In the configuration illustrated in FIG. 12, a frame portion 206 is provided in a region overlapping the first electrode 110 in a planar view. The frame portion 206 is formed of a hard material with low heat conductivity. For example, the frame portion 206 is a frame made of resin, such as epoxy resin. It makes it easier to transmit ultrasonic waves to a bonded portion through the frame portion 206.

In a case where a resin frame is used as the frame portion 206, because its heat conductivity is lower than those of a ceramic frame or a metal ceramic, for example, heat is less likely to be transmitted through the resin frame than these frames. As compared with a case where a hollow space exists without the frame portion 206 provided below the semiconductor substrate 103, heat inflow from the heat generation surface of the Peltier element 106 increases. For this reason, the frame portion 206 desirably has a width as thin as possible. Specifically, when the width of the first electrode 110 is about 50 μm to 100 μm, it is desirable that the width of the frame portion 206 is set up to a size of about ten times the electrode size (about 0.5 mm to 1 mm) in such a manner that a slight deviation can be allowed.

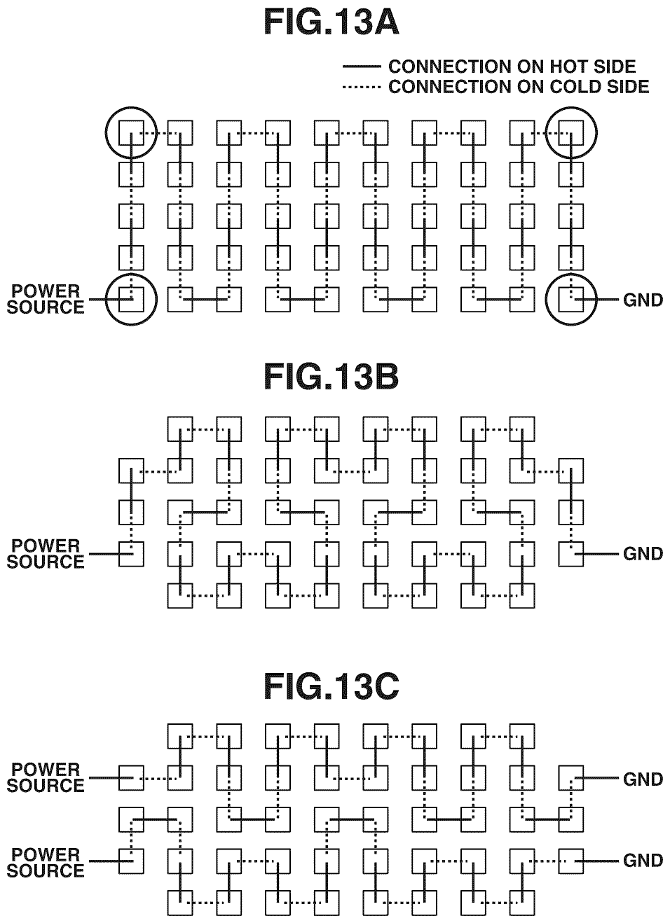

FIGS. 13A to 13C each illustrate an arrangement example of the Peltier element 106 of the electronic component illustrated in FIG. 11C.

FIG. 13A is a top view illustrating a connection relationship of a normal Peltier element 106. Columnar semiconductors are arranged in an array, the connection on the heat generation side that is indicated by a solid line connects semiconductors on the front side of the drawing, and the connection on the heat absorption side that is indicated by a dotted line connects semiconductors on the rear side of the drawing. The semiconductors are connected to each other by a single line from a power source PAD (electrode 203 in FIG. 9) and a ground PAD (electrode 204 in FIG. 9) that are provided in the conducting space.

As an example of the arrangement of the Peltier element 106, FIG. 13B illustrates a configuration in which no semiconductor is arranged at four corners when semiconductors are arranged in a rectangular shape. By employing such arrangement, reliability can be improved. Due to a temperature difference between a high temperature side and a low temperature side of a Peltier element, heat expansion occurs in the material of the high temperature side and heat contraction occurs in the material of the low temperature side, stress is accordingly generated in N-type semiconductors and P-type semiconductors. The stress becomes the highest at the four corner semiconductors, which is the reason for employing the arrangement illustrated in FIG. 13B.

In FIG. 13B, one semiconductor is removed from a semiconductor column, but three or four semiconductors may be removed from a corner. The connection relationship between semiconductors is not limited to the configuration illustrated in FIG. 13B, and it is sufficient that semiconductors are connected by a single line from a power source to a ground. As illustrated in FIG. 13C, a configuration in which semiconductor groups each including semiconductors connected from a power source to a ground by a single line are provided in parallel may be employed.

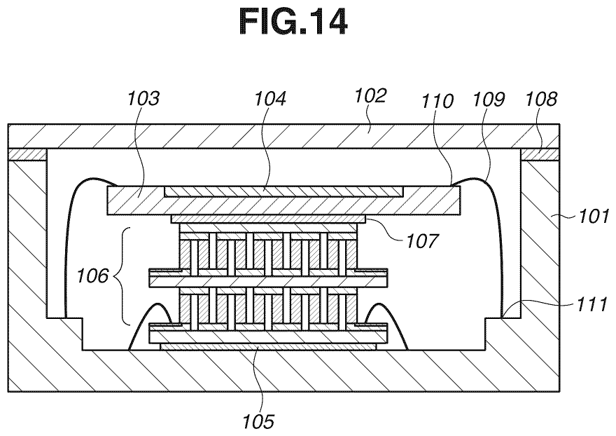

As illustrated in FIG. 14, the Peltier element 106 may have a configuration in which a plurality of Peltier elements 106 is vertically stacked. At this time, a heatsink of an upper Peltier element 106 also serves as a heatsink of a lower Peltier element 106. By vertically stacking a plurality of Peltier elements 106, it is possible to increase the difference ΔT between the high temperature side temperature Th and the low temperature side temperature Tc, and the improvement in cooling capacity can be expected.

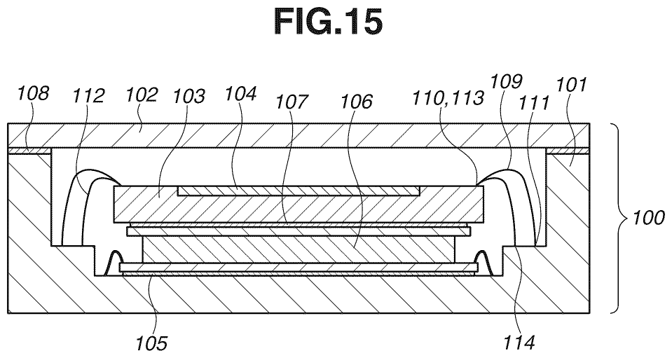

An electronic component according to a third exemplary embodiment will be described with reference to FIGS. 15 to 22B.

FIG. 15 is a cross-sectional view illustrating a configuration example of the electronic component according to the present exemplary embodiment. FIG. 16 is a plan view of the electronic component according to the present exemplary embodiment that is viewed from the optical member 102 side. In the electronic component illustrated in the first exemplary embodiment, the semiconductor substrate 103 and the base member 101 are electrically connected by the conductive wires 109 of one type. In FIG. 15, a third electrode 113 is provided on the semiconductor substrate 103 in addition to the first electrode 110, and a fourth electrode 114 is provided on the base member 101 in addition to the second electrode 111. The first electrode 110 and the second electrode 111 are connected by the conductive wire 109, and the third electrode 113 and the fourth electrode 114 are connected by a second conductive wire 112. The fourth electrode 114 is provided on the outer peripheral side of the electronic component as compared with the second electrode 111. Here, the conductive wire 109 is a signal line or a control line, for example, and the second conductive wire 112 is a wire for transmitting a power voltage or a ground voltage. As illustrated in FIGS. 15 and 16, by employing a wire shorter than the conductive wire 109 as the second conductive wire 112, it is possible to reduce electric resistance and inductance of the second conductive wire 112. In a case where the second conductive wire 112 is a wire for transmitting a power voltage or a ground voltage, a voltage drop can be prevented. Because the conductive wire 109 is a wire similarly to that in the first exemplary embodiment and longer than the second conductive wire 112, an effect of suppressing a heat flow from the Peltier element 106 can be obtained. In order to further enhance the effect of suppressing a heat flow, the length of the conductive wire 109 may be further increased. The layout pattern of the conductive wire 109 and the second conductive wire 112 that is illustrated in FIG. 16 is an example. As another example, for example, the layout in which the second conductive wire 112 is arranged at the corners between sides of the semiconductor substrate 103 can be employed. The layout can be employed based on a relationship of circuit arrangement of the semiconductor substrate 103. With this configuration, it is possible to achieve both of the prevention of a voltage drop and the suppression of a heat flow from the Peltier element 106.

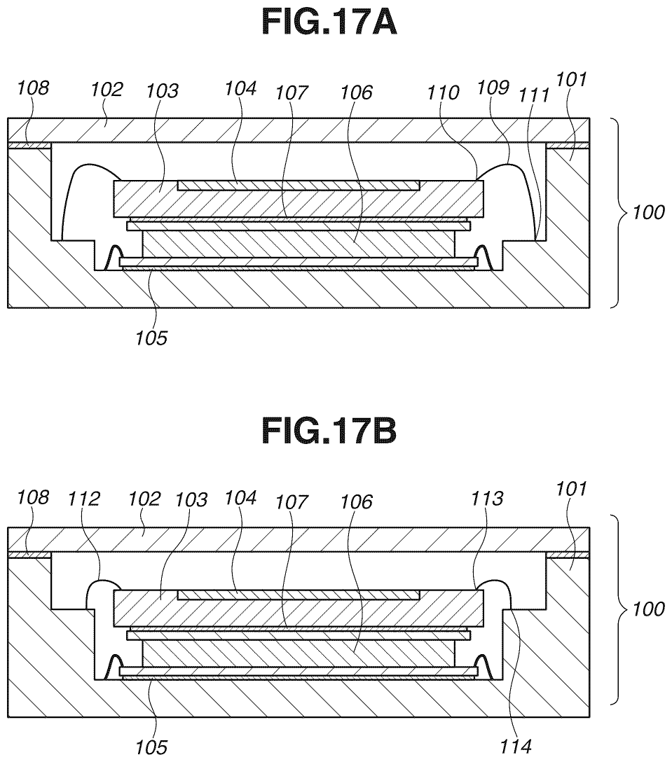

A configuration example of the conductive wire 109 and the second conductive wire 112 according to the present exemplary embodiment will be described. FIGS. 17A and 17B are cross-sectional views illustrating portions near the conductive wire 109 and the second conductive wire 112. FIG. 17A is a cross-sectional view illustrating the portion near the conductive wire 109, and FIG. 17B is a cross-sectional view illustrating the portion near the second conductive wire 112. As illustrated in FIG. 17B, the fourth electrode 114 may be provided at a position higher than the second electrode 111 (a region of the base member 101 in which the fourth electrode 114 is provided may be formed at a position higher than a region in which the second electrode 111 is provided), and the second conductive wire 112 may have a length shorter than that in the configuration illustrated in FIGS. 15 and 16. It is possible to further reduce electric resistance and inductance of the second conductive wire 112. At this time, the second conductive wire 112 can be laid by bringing down the capillary by a small amount, or the second conductive wire 112 can be laid by bringing up the capillary from the third electrode 113 toward the fourth electrode 114. Thus, a conductive wire can be formed using a method of performing wire bonding from the third electrode 113 toward the fourth electrode 114 or using the BSOB method. The arrangement layout of the second electrode 111 and the fourth electrode 114 may be a layout in which the second electrode 111 of the base member 101 and the fourth electrode 114 are alternately arranged, and the conductive wire 109 and the second conductive wire 112 are alternately arranged. As illustrated in FIG. 16, a layout in which a plurality of second conductive wires 112 is adjacently arranged and a plurality of conductive wires 109 is adjacently arranged may be employed. In the case of the layout in which the conductive wire 109 and the second conductive wire 112 are alternately arranged, because the height of an electrode alternately varies, a distance between electrodes is increased in such a manner as to prevent the capillary and the base member 101 from interfering with each other at the time of wire bonding of these conductive wires. For this reason, the electronic component sometimes is increased in size. On the other hand, in the configuration illustrated in FIG. 16, it is sufficient that a distance between electrodes in a portion where the conductive wire 109 and the second conductive wire 112 are adjacent to each other is greater than at least one of a distance between electrodes of a plurality of conductive wires 109, and a distance between electrodes of a plurality of second conductive wires 112. With this configuration, it is possible to reduce the size of the electronic component as compared with layout in which the conductive wire 109 and the second conductive wire 112 are alternately arranged.

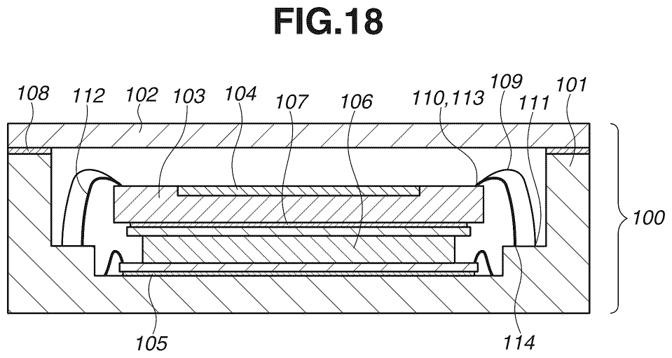

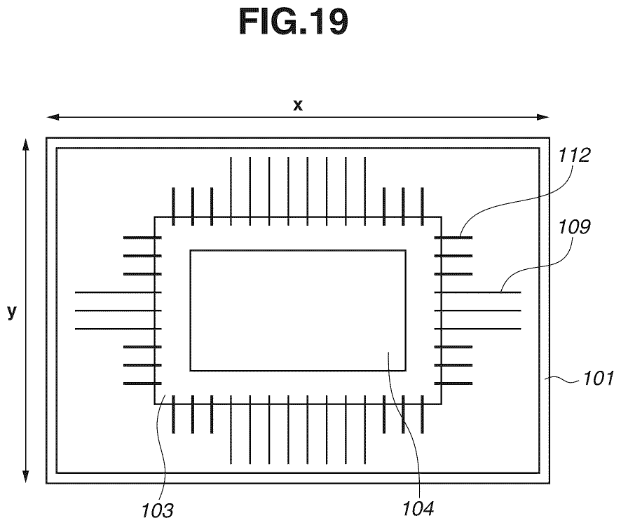

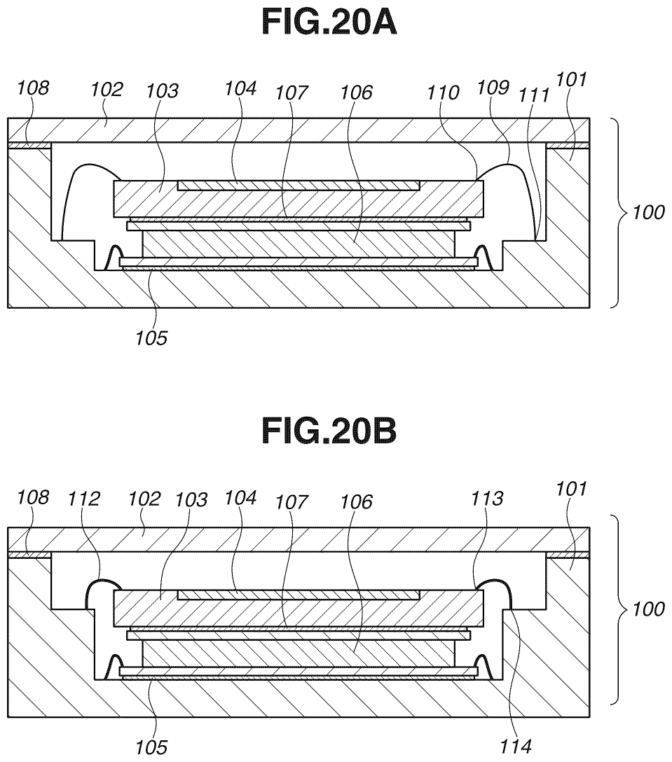

FIG. 18 is a cross-sectional view illustrating a configuration example of the electronic component according to the present exemplary embodiment. FIG. 19 is a plan view of the electronic component in FIG. 18 that is viewed from the optical member 102 side. FIGS. 20A and 20B are cross-sectional views illustrating portions near the conductive wire 109 and the second conductive wire 112 according to the present exemplary embodiment. FIG. 20A is a cross-sectional view illustrating the portion near the conductive wire 109, and FIG. 20B is a cross-sectional view illustrating the portion near the second conductive wire 112. Because the second conductive wire 112 is thicker than the conductive wire 109 as compared with that illustrated in FIGS. 15 and 16, it is possible to further reduce electric resistance and inductance of the second conductive wire 112.

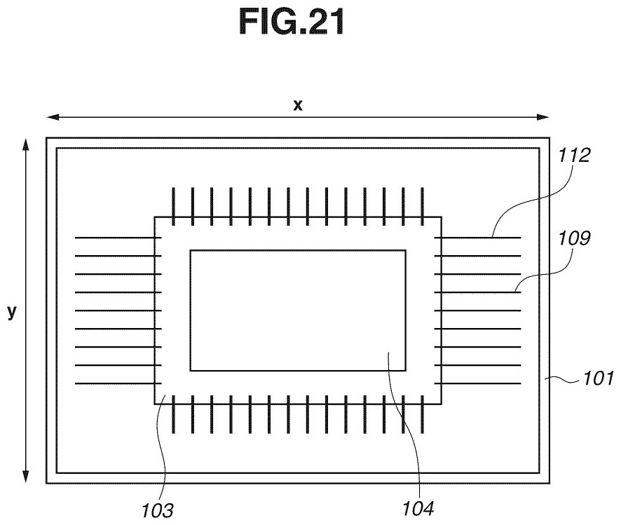

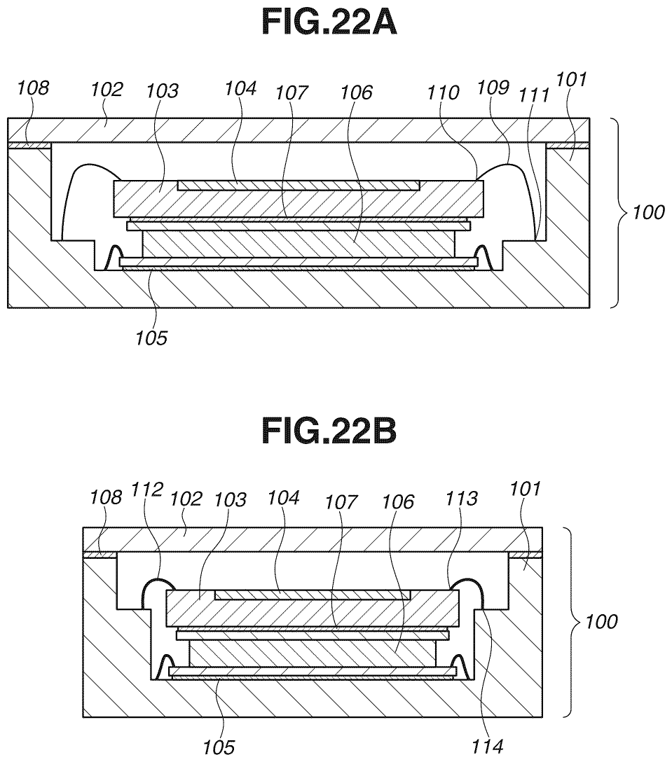

FIG. 21 is a plan view of the electronic component according to the present exemplary embodiment that is viewed from the optical member 102 side. A layout in which the conductive wires 109 and the second conductive wires 112 are separately arranged on different sides of the semiconductor substrate 103 may be employed. FIGS. 22A and 22B are cross-sectional views each illustrating the electronic component according to the present exemplary embodiment. FIG. 22A is a cross-sectional view in a long side direction and FIG. 22B is a cross-sectional view in a short side direction. In addition to separately arranging the conductive wires 109 and the second conductive wires 112 on different sides of the semiconductor substrate 103, the height of the fourth electrode 114 may be increased and the height of the second conductive wire 112 may be decreased. Because the second conductive wires 112 are thicker and shorter than the conductive wires 109, it is possible to further reduce electric resistance and inductance.

In the above-described configuration example, the conductive wire 109 and the second conductive wire 112 may be made of the same material or may be made of different materials. As described in the first exemplary embodiment, in order to enhance the effect of suppressing a heat flow by increasing thermal resistance, a wire with thermal conductivity smaller than 300 W/mK that contains a gold alloy or aluminum as a main material is desirable rather than a gold wire.

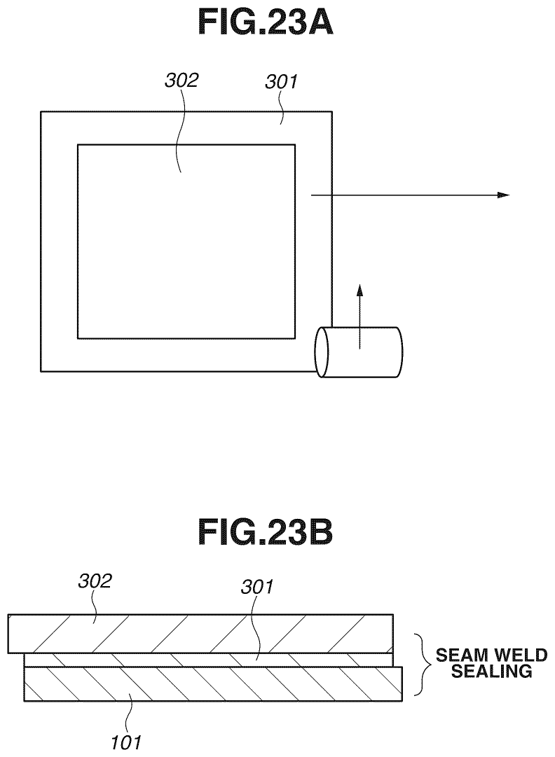

An electronic component according to a fourth exemplary embodiment will be described with reference to FIGS. 23A and 23B.

In the electronic component illustrated in the first exemplary embodiment, the base member 101 and the optical member 102 are sealed by an adhesive. For heat insulation of the inside of the package, vacuum sealing is performed in some cases. For the sake of upper temperature limits of the pixel region 104 and the Peltier element 106, sealing cannot be performed at high temperature. In view of the foregoing, seam weld sealing may be performed in which the base member 101 is pressure-bonded to an optical member 302 equipped with a metal frame 301 by applying heat and load to the optical member 302. By the seam weld sealing, vacuum sealing can be performed within the upper temperature limits of the pixel region 104 and the Peltier element 106.

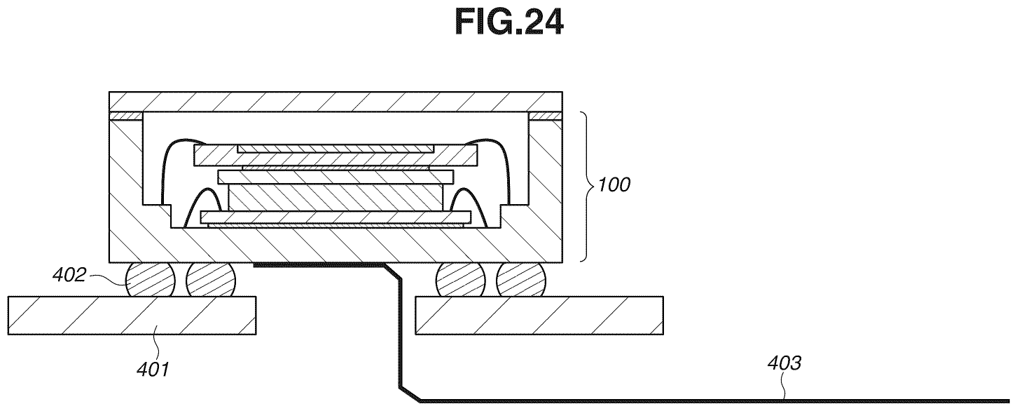

An electronic component according to the fifth exemplary embodiment will be described with reference to FIGS. 24 to 26D.

In a case where the LGA is employed as a package configuration, the package is mounted on a secondary substrate by reflow processing. Here, the secondary substrate is the PCB substrate 401, for example. The PCB substrate 401 may have an opening portion as illustrated in FIG. 24, and a thermal path for releasing heat through the opening portion using a member with high thermal conductivity (for example, the carbon graphite sheet 403) may be formed, but the opening portion is not essential.

As described above, in order to prevent the Peltier element 106 from being damaged due to the melting of solder contained in the Peltier element 106 in the reflow processing, a material with a low melting point, such as resin reinforced solder that can be used in a reflow furnace at low temperature of 200° C. or less, more desirably 180° C. or less, is used.

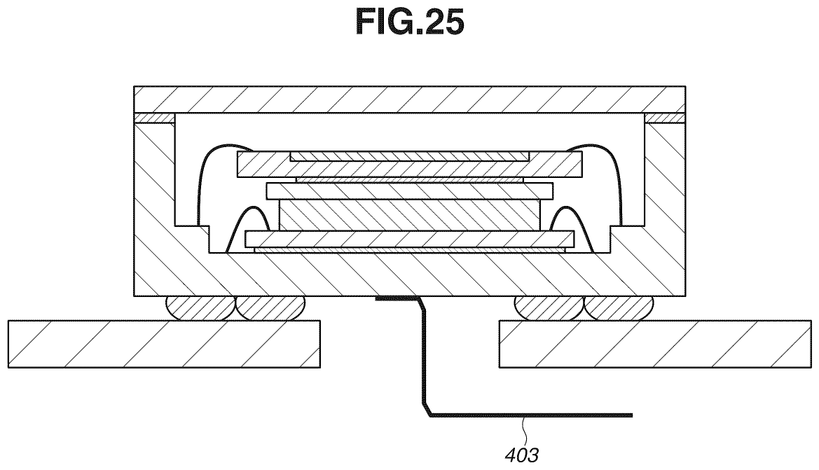

The weight of the electronic component according to the present exemplary embodiment is heavy because the Peltier element 106 is mounted. Accordingly, there is a concern of a short circuit (FIG. 25) attributed to solder crushing of solder 402 arranged between the electronic component and the PCB substrate 401.

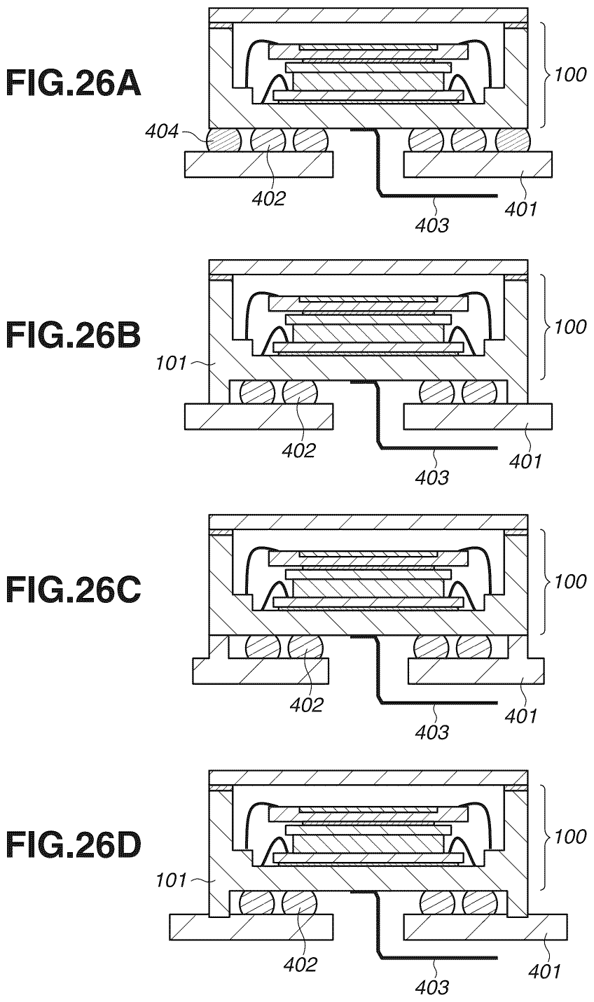

As illustrated in FIG. 26A, in order to prevent solder crushing, a spacer 404 may be arranged between the base member 101 and the PCB substrate 401.

As a variation of the spacer 404, as illustrated in FIG. 26B, the base member 101 may be protruded toward the PCB substrate 401 side and used as a spacer. In this case, because the rear surface side of the base member 101 can be polished, improvements in flatness and parallelism can be expected.

In contrast, as illustrated in FIG. 26C, the PCB substrate 401 may be protruded toward the base member 101 side and used as a spacer. By making the base member 101 protrude toward the PCB substrate 401 side and providing a recess portion in the PCB substrate 401 as illustrated in FIG. 26D, the spacer may be used for positioning by fitting.

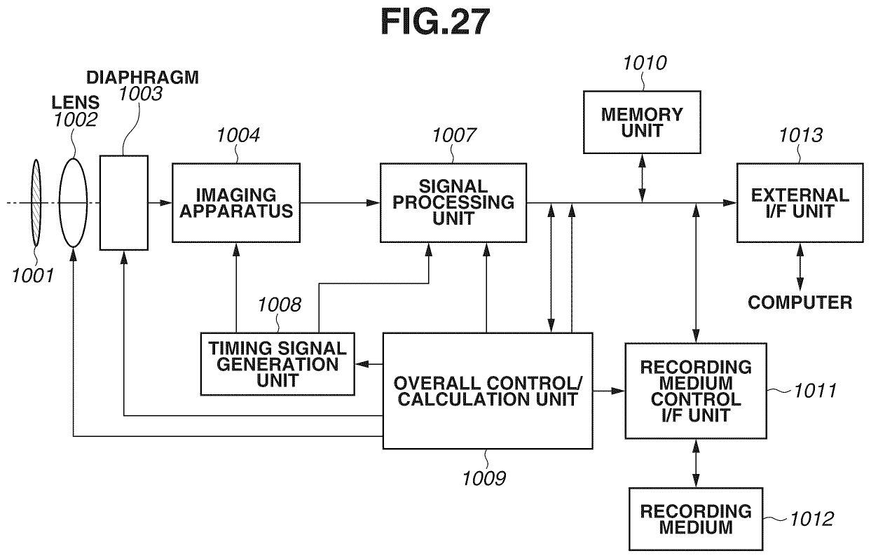

A photoelectric conversion system according to a sixth exemplary embodiment will be described with reference to FIG. 27. FIG. 27 is a block diagram illustrating a schematic configuration of the photoelectric conversion system according to the present exemplary embodiment.

Any of the electric components (hereinafter also referred to as photoelectric conversion apparatuses) described in the above-described first to fifth exemplary embodiments can be applied as a photoelectric conversion apparatus to various photoelectric conversion systems. Examples of photoelectric conversion systems to which the electric component can be applied include a digital still camera, a digital camcorder, a monitoring camera, a copier, a facsimile, a mobile phone, an in-vehicle camera, and an observation satellite. A camera module including an optical system, such as a lens, and an imaging apparatus is also included in the examples of photoelectric conversion systems. As an example of these photoelectric conversion systems, FIG. 27 exemplarily illustrates a block diagram of a digital still camera.

The photoelectric conversion system exemplified in FIG. 27 includes an imaging apparatus 1004 serving as an example of the photoelectric conversion apparatus, a lens 1002 that forms an optical image of a subject on the imaging apparatus 1004, a diaphragm 1003 for varying an amount of light passing through the lens 1002, and a barrier 1001 for protecting the lens 1002. The lens 1002 and the diaphragm 1003 serve as an optical system that condenses light onto the imaging apparatus 1004. The imaging apparatus 1004 is the photoelectric conversion apparatus (imaging apparatus) according to any of the above-described exemplary embodiments, and converts an optical image formed by the lens 1002 into an electric signal.

The photoelectric conversion system further includes a signal processing unit 1007 serving as an image generation unit that generates an image by processing an output signal output by the imaging apparatus 1004. The signal processing unit 1007 performs an operation of outputting image data after performing various types of correction and compression as desired. The signal processing unit 1007 may be formed on a semiconductor substrate on which the imaging apparatus 1004 is provided or may be formed on a semiconductor substrate different from the semiconductor substrate on which the imaging apparatus 1004 is provided. The imaging apparatus 1004 and the signal processing unit 1007 may be formed on the same semiconductor substrate.

The photoelectric conversion system further includes a memory unit 1010 for temporarily storing image data, and an external interface unit (external I/F unit) 1013 for communicating with an external computer. The photoelectric conversion system further includes a recording medium 1012, such as a semiconductor memory, for recording or reading out captured image data, and a recording medium control interface unit (recording medium control I/F unit) 1011 for performing recording onto or readout from the recording medium 1012. The recording medium 1012 may be built into the photoelectric conversion system, or may be detachably attached to the photoelectric conversion system.

The photoelectric conversion system further includes an overall control/calculation unit 1009 that controls various types of calculation and the entire digital still camera, and a timing signal generation unit 1008 that outputs various timing signals to the imaging apparatus 1004 and the signal processing unit 1007. The timing signals may be input from the outside. The photoelectric conversion system preferably includes at least the imaging apparatus 1004 and the signal processing unit 1007 that processes an output signal output from the imaging apparatus 1004.

The imaging apparatus 1004 outputs an imaging signal to the signal processing unit 1007. The signal processing unit 1007 outputs image data after performing predetermined signal processing on the imaging signal output from the imaging apparatus 1004. The signal processing unit 1007 generates an image using the imaging signal.

In this manner, according to the present exemplary embodiment, a photoelectric conversion system to which the photoelectric conversion apparatus (imaging apparatus) according to any of the above-described exemplary embodiments is applied can be realized.

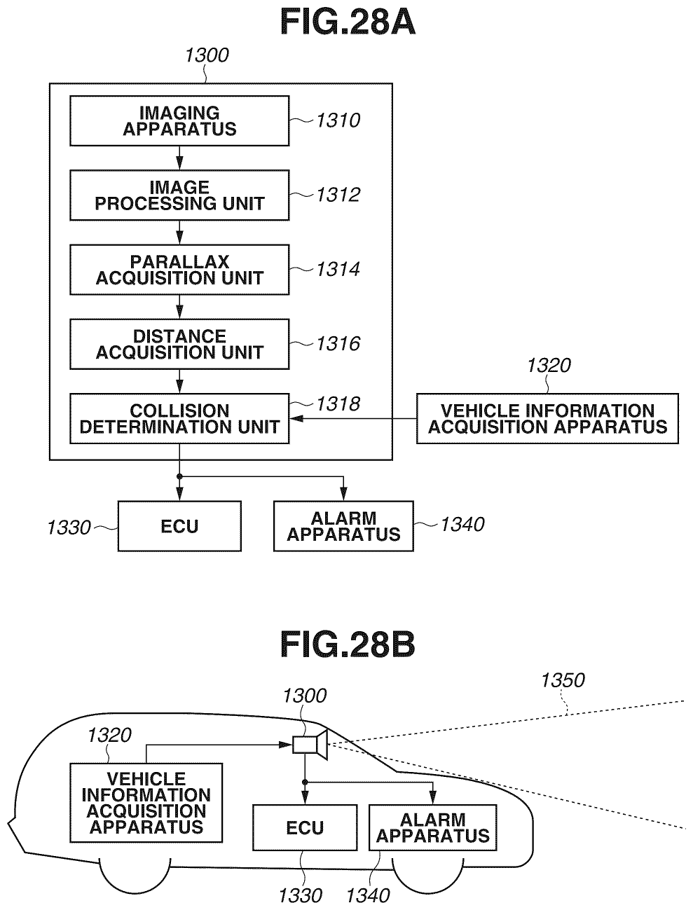

A photoelectric conversion system and a movable body according to a seventh exemplary embodiment will be described with reference to FIGS. 28A and 28B. FIGS. 28A and 28B are diagrams illustrating configurations of the photoelectric conversion system and the movable body according to the present exemplary embodiment.

FIG. 28A illustrates an example of a photoelectric conversion system related to an in-vehicle camera. A photoelectric conversion system 1300 includes an imaging apparatus 1310. The imaging apparatus 1310 is the photoelectric conversion apparatus (imaging apparatus) according to any of the above-described exemplary embodiments. The photoelectric conversion system 1300 includes an image processing unit 1312 that performs image processing on a plurality of pieces of image data acquired by the imaging apparatus 1310. The photoelectric conversion system 1300 further includes a distance acquisition unit 1316 that calculates a distance to a target object, and a collision determination unit 1318 that determines whether collision is likely to occur, based on the calculated distance. In this example, the distance acquisition unit 1316 may acquire distance information regarding a distance to a Time of Flight (ToF) target object, or may acquire distance information using parallax information. More specifically, the distance information is information regarding a parallax, a defocus amount, and a distance to a target object. The collision determination unit 1318 may determine a likelihood of collision using any of these pieces of distance information. The distance acquisition unit 1316 may be implemented by dedicatedly designed hardware, or may be implemented by a software module. Alternatively, the distance acquisition unit 1316 unit may be implemented by a field programmable gate array (FPGA) or an application specific integrated circuit (ASIC), or may be implemented by the combination of these.

The photoelectric conversion system 1300 is connected with a vehicle information acquisition apparatus 1320 and can acquire vehicle information, such as a vehicle speed, a yaw rate, or a rudder angle. In addition, an electronic control unit (ECU) 1330 is connected to the photoelectric conversion system 1300. The ECU 1330 serves as a control apparatus that outputs a control signal for generating braking force for a vehicle based on a determination result obtained by the collision determination unit 1318. The photoelectric conversion system 1300 is also connected with an alarm apparatus 1340 that issues an alarm to a driver based on a determination result obtained by the collision determination unit 1318. For example, in a case where the determination result obtained by the collision determination unit 1318 indicates a high likelihood of collision, the ECU 1330 performs vehicle control to avoid collision or reduce damages by braking, releasing an accelerator, or decreasing engine output. The alarm apparatus 1340 issues an alarm to a user by issuing an alarm, such as sound, displaying warning information on a screen of a car navigation system, or vibrating a seatbelt or a steering wheel.

In the present exemplary embodiment, the photoelectric conversion system 1300 captures an image of the periphery of the vehicle, such as the front side or the rear side, for example. FIG. 28B illustrates the photoelectric conversion system 1300 for capturing an image of a vehicle front side (imaging range 1350). The vehicle information acquisition apparatus 1320 issues an instruction to the photoelectric conversion system 1300 or the imaging apparatus 1310. With this configuration, the accuracy of distance measurement can be further enhanced.

The above description has been given of an example in which control is performed in such a manner as not to collide with another vehicle. The photoelectric conversion system can also be applied to the control for performing automatic operation by following another vehicle, or the control for performing automatic operation in such a manner as not to drift out of a lane. Furthermore, the photoelectric conversion system can be applied to a movable body (moving apparatus), such as a vessel, an aircraft, or an industrial robot, for example, in addition to a vehicle, such as an automobile. This movable body includes either one or both of a drive force generation unit that generates drive force to be mainly used for the movement of the movable body, and a rotator to be mainly used for the movement of the movable body. The drive force generation unit can be an engine, a motor, or the like. The rotator can be a tire, a wheel, a screw of a ship, a propeller of a flight vehicle, or the like. Moreover, the photoelectric conversion system can be applied to a device that extensively uses object recognition, such as an intelligent transport system (ITS), in addition to a movable body.

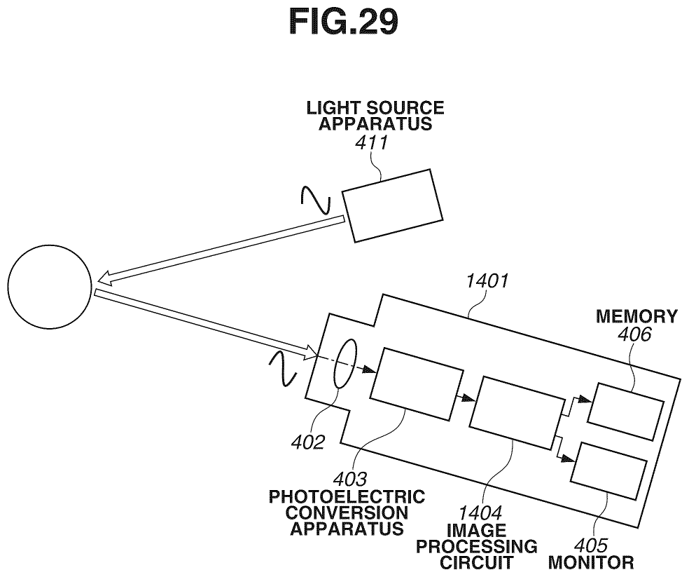

A photoelectric conversion system according to an eighth exemplary embodiment will be described with reference to FIG. 29. FIG. 29 is a block diagram illustrating a configuration example of a distance image sensor serving as a photoelectric conversion system according to the present exemplary embodiment.

As illustrated in FIG. 29, a distance image sensor 1401 includes an optical system 402, a photoelectric conversion apparatus 408, an image processing circuit 1404, a monitor 405, and a memory 406. The distance image sensor 1401 can acquire a distance image corresponding to a distance to a subject, by receiving light (modulated light or pulse light) that has been projected from a light source apparatus 411 toward the subject, and reflected on the front surface of the subject.

The optical system 402 includes one or a plurality of lenses. The optical system 402 forms an image on a light receiving surface (sensor portion) of the photoelectric conversion apparatus 408 while guiding image light (incident light) from the subject to the photoelectric conversion apparatus 408.

The photoelectric conversion apparatus described in each of the above exemplary embodiments is applied to the photoelectric conversion apparatus 408, and a distance signal indicating a distance obtained from a light receiving signal output from the photoelectric conversion apparatus 408 is supplied to the image processing circuit 1404.

The image processing circuit 1404 performs image processing for constructing a distance image, based on the distance signal supplied from the photoelectric conversion apparatus 408. Then, a distance image (image data) obtained by the image processing is supplied to the monitor 405 and displayed thereon, or supplied to the memory 406 and stored (recorded) therein.

By applying the above-described electric component or photoelectric conversion apparatus, the distance image sensor 1401 having the above-described configuration can acquire a more accurate distance image in accordance with improvement of pixel characteristics, for example.

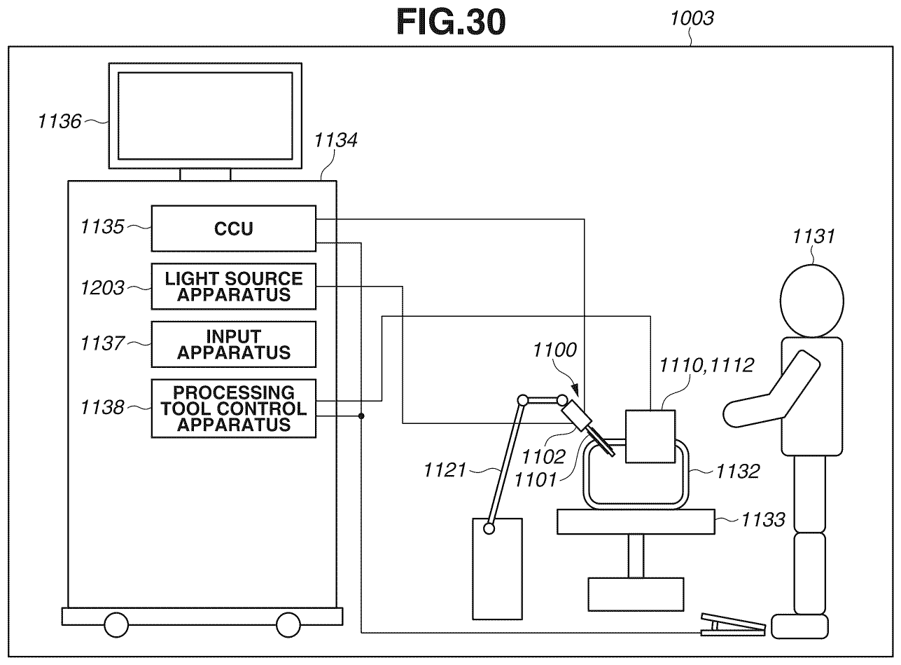

A photoelectric conversion system according to a ninth exemplary embodiment will be described with reference to FIG. 30. FIG. 30 is a diagram illustrating an example of a schematic configuration of an endoscopic operation system serving as a photoelectric conversion system of the present exemplary embodiment.

FIG. 30 illustrates a state in which an operator (doctor) 1131 is performing an operation on a patient 1132 lying on a patient bed 1133, using an endoscopic operation system. As illustrated in FIG. 30, the endoscopic operation system includes an endoscope 1100, a surgical tool 1110, and a cart 1134 equipped with various apparatuses for an endoscopic operation.

The endoscope 1100 includes a lens barrel 1101 having a region to be inserted into a body cavity of the patient 1132 by a predetermined length from a distal end, and a camera head 1102 connected to a base end of the lens barrel 1101. In the example illustrated in FIG. 30, the endoscope 1100 formed as a so-called rigid scope including the rigid lens barrel 1101 is illustrated, but the endoscope 1100 may be formed as a flexible scope including a so-called flexible lens barrel.

An opening portion into which an objective lens is fitted is provided at the distal end of the lens barrel 1101. A light source apparatus is connected to the endoscope 1100, and light generated by the light source apparatus is guided to the distal end of the lens barrel 1101 by a light guide extended inside the lens barrel 1101, and emitted onto an observation target in the body cavity of the patient 1132 via the objective lens. The endoscope 1100 may be a forward-viewing endoscope, or may be a forward-oblique viewing endoscope or a side-viewing endoscope.

An optical system and a photoelectric conversion apparatus are provided inside the camera head 1102. Reflected light (observation light) from an observation target is condensed by the optical system to the photoelectric conversion apparatus. The observation light is photoelectrically converted by the photoelectric conversion apparatus, and an electric signal corresponding to the observation light, i.e., image signal corresponding to an observed image, is generated. The photoelectric conversion apparatus (imaging apparatus) described in each of the above exemplary embodiments can be used as the photoelectric conversion apparatus. The image signal is transmitted to a camera control unit (CCU) 1135 as RAW data. The image signal is transmitted to a camera control unit (CCU) 1135 as RAW data.

The CCU 1135 includes a central processing unit (CPU) or a graphics processing unit (GPU), and comprehensively controls operations of the endoscope 1100 and a display device 1136. Furthermore, the CCU 1135 receives an image signal from the camera head 1102, and performs various types of image processing, such as development processing (demosaic processing), on the image signal to display an image that is based on the image signal.

Based on the control from the CCU 1135, the display device 1136 displays an image that is based on the image signal on which image processing has been performed by the CCU 1135.

The light source apparatus includes a light source, such as a light emitting diode (LED), and supplies the endoscope 1100 with irradiation light at the time of capturing an image of an operative site.

An input apparatus 1137 is an input interface with the endoscopic operation system. A user can input various types of information and instructions to the endoscopic operation system via the input apparatus 1137.

A processing tool control apparatus 1138 controls the driving of an energy processing tool 1112 for cauterizing or cutting a tissue, or sealing a blood vessel.

The light source apparatus that supplies the endoscope 1100 with irradiation light at the time of capturing an image of an operative site can include, for example, an LED, a laser light source, or a white light source including a combination of these. In a case where a white light source includes a combination of red-green-blue (RGB) laser light sources, because output intensity and an output timing of each color (each wavelength) can be controlled highly accurately, white balance of a captured image can be adjusted in the light source apparatus. In this case, by emitting laser light from each RGB laser light source onto an observation target in a time division manner, and controlling the driving of an image sensor of the camera head 1102 in synchronization with the emission timing, an image corresponding to each of RGB can also be captured in a time division manner. According to the method, a color image can be obtained without providing a color filter in the image sensor.

The driving of the light source apparatus may be controlled in such a manner as to change the intensity of light to be output, every predetermined time. By acquiring images in a time division manner by controlling the driving of the image sensor of the camera head 1102 in synchronization with the change timing of the light intensity, and combining the images, it is possible to generate a high dynamic range image without so-called blocked up shadows and blown out highlights.

The light source apparatus may be configured to supply light in a predetermined wavelength band adapted to special light observation. In the special light observation, for example, wavelength dependency of light absorption in body tissues is utilized. Specifically, by emitting light in a narrow band as compared with irradiation light (i.e., white light) in normal observation, an image of a predetermined tissue, such as a blood vessel of a superficial portion of a mucous membrane, is captured with high contrast. Alternatively, in special light observation, fluorescent observation for obtaining an image by fluorescence generated by emitting excitation light may be performed. In the fluorescent observation, fluorescence from a body tissue can be observed by emitting excitation light onto the body tissue, or a fluorescent image can be obtained by locally injecting reagent, such as indocyanine green (ICG), into a body tissue and emitting excitation light suitable for a fluorescence wavelength of the reagent, onto the body tissue. The light source apparatus can be configured to supply narrow-band light and/or excitation light adapted to such special light observation.

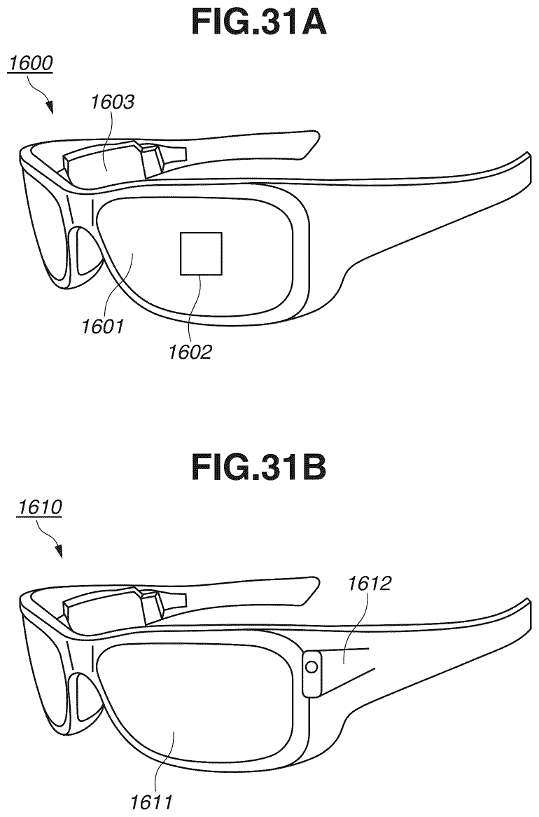

A photoelectric conversion system according to a tenth exemplary embodiment will be described with reference to FIGS. 31A and 31B. FIG. 31A is a diagram illustrating an example of a configuration of eyeglasses 1600 (smart glasses) serving as a photoelectric conversion system according to the present exemplary embodiment. The eyeglasses 1600 include a photoelectric conversion apparatus 1602. The photoelectric conversion apparatus 1602 is the photoelectric conversion apparatus (imaging apparatus) described in each of the above-described exemplary embodiments. A display device including a light emission device, such as an organic light emitting diode (OLED) or an LED, may be provided on the rear surface side of a lens 1601. The number of photoelectric conversion apparatuses 1602 may be one or more. A plurality of types of photoelectric conversion apparatuses may be used in combination. An arrangement position of the photoelectric conversion apparatus 1602 is not limited to the position illustrated in FIG. 31A.

The eyeglasses 1600 further include a control apparatus 1603. The control apparatus 1603 functions as a power source that supplies power to the photoelectric conversion apparatus 1602 and the above-described display device. The control apparatus 1603 controls operations of the photoelectric conversion apparatus 1602 and the display device. In the lens 1601, an optical system for condensing light to the photoelectric conversion apparatus 1602 is formed.

FIG. 31B illustrates eyeglasses 1610 (smart glasses) according to one application example. The eyeglasses 1610 include a control apparatus 1612, and the control apparatus 1612 is equipped with a photoelectric conversion apparatus equivalent to the photoelectric conversion apparatus 1602, and a display device. In a lens 1611, an optical system for projecting light emitted from the photoelectric conversion apparatus and the display device in the control apparatus 1612 is formed, and an image is projected onto the lens 1611. The control apparatus 1612 functions as a power source that supplies power to the photoelectric conversion apparatus and the display device, and controls operations of the photoelectric conversion apparatus and the display device. The control apparatus may include a line-of-sight detection unit that detects a line of sight of a wearer. Infrared light may be used for the detection of a visual line. An infrared light emission unit emits infrared light onto an eyeball of a user looking at a displayed image. An imaging unit including a light receiving element detects reflected light of the emitted infrared light that has been reflected by the eyeball. A captured image of the eyeball is thereby obtained. By including a reduction unit for reducing light from the infrared light emission unit to a display unit in a planar view, a deterioration in image quality is suppressed.

From a captured image of an eyeball obtained by image capturing using infrared light, a line of sight of a user with respect to a displayed image is detected. An arbitrary known method can be applied to line-of-sight detection that uses a captured image of an eyeball. As an example, a line-of-sight detection method that is based on a Purkinje image obtained by reflection of irradiation light on a cornea can be used.

More specifically, line-of-sight detection processing that is based on the pupil center corneal reflection is performed. By calculating an eye vector representing the direction (rotational angle) of an eyeball, based on an image of a pupil and a Purkinje image that are included in a captured image of the eyeball, using the pupil center corneal reflection, a line of sight of a user is detected.

The display device of the present exemplary embodiment includes the photoelectric conversion apparatus including a light receiving element, and a displayed image of the display device may be controlled based on line-of-sight information on the user from the photoelectric conversion apparatus.

Specifically, in the display device, a first eyeshot region viewed by the user, and a second eyeshot region other than the first eyeshot region are determined based on the line-of-sight information. The first eyeshot region and the second eyeshot region may be determined by a control apparatus of the display device, or the first eyeshot region and the second eyeshot region determined by an external control apparatus may be received. In a display region of the display device, a display resolution of the first eyeshot region may be controlled to be higher than a display resolution of the second eyeshot region. In other word, a resolution of the second eyeshot region may be lower than a resolution of the first eyeshot region.

The display region includes a first display region and a second display region different from the first display region. Based on the line-of-sight information, a region with high priority may be determined from the first display region and the second display region. The first display region and the second display region may be determined by a control apparatus of the display device, or the first display region and the second display region determined by an external control apparatus may be received. A resolution of a region with high priority may be controlled to be higher than a resolution of a region other than the region with high priority. In other words, a resolution of a region with relatively low priority may be set to a low resolution.

Artificial intelligence (AI) may be used for determining the first eyeshot region and the region with high priority. The AI may be a model configured to estimate an angle of a line and a distance to a target existing in the line of sight, from an image of an eyeball, using teaching data including an image of the eyeball, and a direction in which the eyeball in the image actually gazes. An AI program may be included in the display device, may be included in the photoelectric conversion apparatus, or may be included in an external apparatus. In a case where an external apparatus includes an AI program, the AI program is transmitted to the display device via communication.

In a case where display control is performed based on line-of-sight detection, the present exemplary embodiment can be desirably applied to smart glasses further including a photoelectric conversion apparatus that captures an image of the outside. The smart glasses can display external information obtained by image capturing, in real time.

The exemplary embodiments described above can be appropriately changed without departing from the technical idea. The disclosure in this specification is not limited to matters described in this specification, and includes all matters that can be identified from this specification and the drawings accompanying this specification. The disclosure in this specification includes a complementary set of individual concepts described in this specification. More specifically, if “A is larger than B” is described in this specification, even if the description “B is not larger than A” is omitted, this specification is assumed to disclose that “B is not larger than A”. This is because, in a case where “A is larger than B” is described, the case is premised based on a case where “B is not larger than A”.

While the present disclosure has been described with reference to exemplary embodiments, it is to be understood that the disclosure is not limited to the disclosed exemplary embodiments. The scope of the following claims is to be accorded the broadest interpretation so as to encompass all such modifications and equivalent structures and functions.

This application claims the benefit of priority from Japanese Patent Applications No. 2023-202720, filed Nov. 30, 2023, and No. 2024-159060, filed Sep. 13, 2024, which are hereby incorporated by reference herein in their entirety.

What is claimed is:

1. An electronic component comprising:
a cooling member;
a semiconductor substrate; and
a base member in which the cooling member and the semiconductor substrate are placed,
wherein the cooling member is arranged between the base member and the semiconductor substrate,
wherein the semiconductor substrate includes a first electrode,
wherein the base member includes a second electrode,
wherein the first electrode and the second electrode are connected by a conductive wire, and
wherein balls are formed on both of a bonded portion of the first electrode and the conductive wire, and a bonded portion of the second electrode and the conductive wire.

2. The electronic component according to claim 1, further comprising an optical member mounted on the base member,
wherein a frame member of the base member that supports the optical member is provided in a first region of a bottom portion, and the cooling member is placed in a second region of the bottom portion, and
wherein the second electrode is provided between the first region and the second region.

3. The electronic component according to claim 1, wherein a stitch is formed on the ball in the bonded portion of the first electrode and the conductive wire.

4. The electronic component according to claim 1, wherein an angle formed by the conductive wire and a normal line of a surface on which the second electrode is arranged is 100 or less.

5. The electronic component according to claim 2, wherein the second electrode is provided at a position closer to the semiconductor substrate than the bottom portion.

6. The electronic component according to claim 1,
wherein the semiconductor substrate includes a third electrode,
wherein the base member includes a fourth electrode,
wherein the third electrode and the fourth electrode are connected by a second conductive wire, and
wherein a thermal resistance of the second conductive wire is lower than a thermal resistance of the conductive wire.

7. The electronic component according to claim 6, wherein balls are formed on both of a bonded portion of the third electrode and the second conductive wire, and a bonded portion of the fourth electrode and the second conductive wire.

8. The electronic component according to claim 6, wherein a stitch is formed on the ball in the bonded portion of the third electrode and the second conductive wire.

9. The electronic component according to claim 6, wherein the fourth electrode is arranged at a position closer to an outer periphery of the electronic component than the second electrode.

10. The electronic component according to claim 6, wherein, when viewed from the base member, the fourth electrode is arranged at a position higher than the second electrode.

11. The electronic component according to claim 6, wherein the second conductive wire is shorter than the conductive wire.

12. The electronic component according to claim 6, wherein the second conductive wire is thicker than the conductive wire.

13. The electronic component according to claim 6, wherein the second conductive wire has higher thermal conductivity than thermal conductivity of the conductive wire.

14. The electronic component according to claim 1, wherein the cooling member is a Peltier element.

15. The electronic component according to claim 1, wherein the base member contains alumina.

16. The electronic component according to claim 1, wherein the base member contains aluminum nitride.

17. The electronic component according to claim 1, wherein the conductive wire contains gold.

18. The electronic component according to claim 1, wherein the conductive wire contains aluminum.

19. The electronic component according to claim 1, wherein a distance in a vertical direction between the second electrode and an uppermost part of the conductive wire is 1 millimeter (mm) or more.

20. The electronic component according to claim 2, wherein, in a planar view, the second region is encompassed in a region in which the semiconductor substrate is arranged.

21. The electronic component according to claim 2, wherein the semiconductor substrate includes a plurality of pixels arranged in an array.

22. The electronic component according to claim 21, wherein, in a planar view, the second region is encompassed in a region in which the plurality of pixels is arranged.

23. The electronic component according to claim 2, wherein the base member and the optical member are bonded by an adhesive.

24. The electronic component according to claim 2, wherein the base member and the optical member are bonded by a metal frame.

25. The electronic component according to claim 1,
wherein the base member is mounted on a secondary substrate via solder, and
wherein the base member includes a member protruding toward the secondary substrate.

26. The electronic component according to claim 14, the cooling member includes a plurality of the stacked Peltier elements.

27. The electronic component according to claim 2, wherein a plurality of the cooling members is placed in the second region.

28. A device comprising:
the electronic component according to claim 1; and
a processing apparatus configured to process a signal output from the electronic component.
